(19) United States
(12) Patent Application Publication
(10) Pub. No.: US 2024/0351592 A1
(43) Pub. Date: Oct. 24, 2024

(54) SUPPORT TOOLS FOR AV TESTING

(71) Applicant: Five AI Limited, Cambridge (GB)

(72) Inventors: Jonathan Sadeghi, Cambridge (GB); Blaine Rogers, Cambridge (GB); James Gunn, Cambridge (GB); Thomas Saunders, Cambridge (GB); Sina Samangooei, Cambridge (GB); Puneet Kumar Dokania, Cambridge (GB); John Redford, Cambridge (GB)

(73) Assignee: Five AI Limited, Cambridge (GB)

(21) Appl. No.: 18/684,606

(22) PCT Filed: Aug. 19, 2022
(86) PCT No.: PCT/EP2022/073253

§ 371 Date: Feb. 16, 2024

(30) Foreign Application Priority Data
Aug. 20, 2021 (GB) 2111986.2

(51) Int. Cl. B60W 50/00; G06F 11/27

(52) U.S. Cl. CPC B60W 50/00; G06F 11/27

(57) ABSTRACT

Performance of a substitute upstream processing component is tested, in order to determine whether that performance is sufficient to support a downstream processing component, within an autonomous driving system, in place of an existing upstream processing component. The existing upstream processing component and the substitute upstream processing component are mutually interchangeable in so far as they provide the same form of outputs interpretable by the downstream processing component, such that either upstream processing component may be used without modification to the downstream processing component. A direct or indirect metric-based comparison is formulated in terms of the resulting performance of the downstream processing component.

### TECHNICAL FIELD

The present disclosure pertains to support tools for use in the testing and development of autonomous vehicle systems.

### BACKGROUND

There have been major and rapid developments in the field of autonomous vehicles. An autonomous vehicle (AV) is a vehicle which is equipped with sensors and control systems which enable it to operate without a human controlling its behaviour. An autonomous vehicle is equipped with sensors which enable it to perceive its physical environment, such sensors including for example cameras, radar and lidar. Autonomous vehicles are equipped with suitably programmed computers which are capable of processing data received from the sensors and making safe and predictable decisions based on the context which has been perceived by the sensors. An autonomous vehicle may be fully autonomous (in that it is designed to operate with no human supervision or intervention, at least in certain circumstances) or semi-autonomous. Semi-autonomous systems require varying levels of human oversight and intervention. An Advanced Driver Assist System (ADAS) and certain levels of Autonomous Driving System (ADS) may be classed as semi-autonomous.

A “level 5” vehicle is one that can operate entirely autonomously in any circumstances, because it is always guaranteed to meet some minimum level of safety. Such a vehicle would not require manual controls (steering wheel, pedals etc.) at all.

By contrast, level 3 and level 4 vehicles can operate fully autonomously but only within certain defined circumstances (e.g. within geofenced areas). A level 3 vehicle must be equipped to autonomously handle any situation that requires an immediate response (such as emergency braking); however, a change in circumstances may trigger a “transition demand”, requiring a driver to take control of the vehicle within some limited timeframe. A level 4 vehicle has similar limitations; however, in the event the driver does not respond within the required timeframe, a level 4 vehicle must also be capable of autonomously implementing a “minimum risk maneuver” (MRM), i.e. some appropriate action(s) to bring the vehicle to safe conditions (e.g. slowing down and parking the vehicle). A level 2 vehicle requires the driver to be ready to intervene at any time, and it is the responsibility of the driver to intervene if the autonomous systems fail to respond properly at any time. With level 2 automation, it is the responsibility of the driver to determine when their intervention is required; for level 3 and level 4, this responsibility shifts to the vehicle's autonomous systems and it is the vehicle that must alert the driver when intervention is required.

In the context of an AV stack, perception generally refers to the AV's ability to interpret the sensor data it captures from its environment (e.g. image, literary, radar etc.). Perception includes, for example, 2D or 3D bounding box detection, location detection, pose detection, motion detection etc. In the context of image processing, such techniques are often classed as “computer vision”, but the term perception encompasses a broader range of sensor modalities, such as lidar, radar etc. Perception can, in tun, support higher-level processing within the Av stack, such as motion prediction, planning etc.

There are different facets to testing the behaviour of the sensors and control systems aboard a particular autonomous vehicle, or a type of autonomous vehicle. AV components may be tested individually and/or in combination.

### SUMMARY

Testing of perception components (object detectors, localization components, classification/segmentation networks etc.) and the like has relied on task-agnostic metrics, most typically accuracy and precision or variants thereof. However, in the context of an autonomous vehicle (AV) system, such components are provided to support specific “downstream” tasks such as prediction and planning.

Herein, tools are provided that facilitate a systematic, metric-based evaluation of perception components and/or other forms of upstream component within an AV system, but formulated in terms of specific downstream task(s) (e.g. planning, prediction etc.) that are supported by an upstream component(s) within an AV system. The performance of upstream components is scored in terms of their effect on downstream task(s), as it is the latter that is ultimately determinative of driving performance. As another example, an upstream component might be a prediction system, for which a metric-based evaluation is formulated in terms of a downstream planning task.

A first aspect herein provides a computer-implemented method of testing performance of a substitute upstream processing component, in order to determine whether the performance of the substitute upstream processing component is sufficient to support a downstream processing component, within an autonomous driving system, in place of an existing upstream processing component, the existing upstream processing component and the substitute upstream processing component mutually interchangeable in so far as they provide the same form of outputs interpretable by the downstream processing component, such that either upstream processing component may be used without modification to the downstream processing component, the method comprising:
applying the existing upstream processing component to a first set of upstream inputs, and thereby obtaining a first set of upstream outputs;
applying the downstream processing component to the first set of upstream outputs, thereby obtaining a first set of downstream outputs;
using the substitute upstream processing component to obtain a second set of upstream outputs for the first set of inputs;
applying the downstream processing component to the second set of upstream outputs, thereby obtaining a second set of downstream outputs;
performing a metric-based comparison of the first and second sets of downstream outputs, thereby computing a numerical performance score for the substitute upstream processing component, the numerical performance score denoting an extent to which the second set of downstream outputs obtained using the substitute upstream processing component matches the first set of downstream outputs obtained using the existing upstream processing component.

The method of the first aspect is based on a direct comparison of the existing upstream processing component and the surrogate, on some downstream metric (i.e. in terms of the relative performance of the downstream processing component).

A second aspect facilitates an indirect comparison of the existing upstream processing component and the substitute upstream processing component on some downstream metric, as an alternative to the direct metric-based comparison of the first and second sets of downstream outputs. The second aspect provides a computer-implemented method of testing performance of a substitute upstream processing component, in order to determine whether the performance of the substitute upstream processing component is sufficient to support a downstream processing component, within an autonomous driving system, in place of an existing upstream processing component, the existing upstream processing component and the substitute upstream processing component mutually interchangeable in so far as they provide the same form of outputs interpretable by the downstream processing component, such that either upstream processing component may be used without modification to the downstream processing component, the method comprising:
applying the existing upstream processing component to a first set of upstream inputs, and thereby obtaining a first set of upstream outputs;
applying the downstream processing component to the first set of upstream outputs, thereby obtaining a first set of downstream outputs;
using the substitute upstream processing component to obtain a second set of upstream outputs for the first set of inputs;
applying the downstream processing component to the second set of upstream outputs, thereby obtaining a second set of downstream outputs;
obtaining a ground truth set of outputs corresponding in form to the first and second sets of upstream outputs, the ground truth set of outputs and the first set of upstream inputs pertaining to a common driving scenario or scene;
applying the downstream processing component to the ground outputs inputs directly, thereby obtaining a ground truth set of downstream outputs;
performing a first metric-based comparison of the first set of downstream outputs and the ground truth set of downstream outputs, thereby computing a first numerical performance score for the existing upstream processing component, the first numerical performance score denoting an extent to which the first set of downstream outputs obtained using the existing upstream processing component matches the ground truth set of downstream outputs;
performing a second metric-based comparison of the second set of downstream outputs and the ground truth set of downstream outputs, thereby computing a second numerical performance score for the substitute upstream processing component, the second numerical performance score denoting an extent to which the second set of downstream outputs obtained using the substitute upstream processing component matches the ground truth set of downstream outputs.

Both aspects enable a metric-based assessment of similarity (directly or indirectly) between the existing upstream processing component and the substitute upstream processing component in terms of similarity of resulting downstream performance (or, to put it another way, whether the substitute upstream processing component is a suitable substitute for the existing upstream processing component, in so far as it results in similar downstream performance). For example, the existing upstream processing component may be a perception component, in which case either method allows the suitability of the substitute processing component to be assessed in terms of whether it results, e.g., planning or prediction performance similar to that attained with the existing perception component (through the direct comparison of the first aspect or the indirect comparison of the second aspect). As another example, the existing upstream processing component may be a prediction system, and the suitability of the substitute processing component may be assessed in terms in term of whether it results in, e.g., similar planning performance.

For example, one aim may be to find a substitute processing component for an existing upstream processing component of an AV stack that can be implemented more efficiently than the existing upstream processing component (e.g. using fewer computational and/or memory resources), but does not materially alter the overall performance of the AV stack. In this case, finding a suitable substitute improves the overall speed or efficiency of the AV stack, without materially altering the substitute performance.

One situation considered is AV stack testing, where the aim is to perform large-scale testing more efficiently by substituting an upstream perception component operating on high-fidelity sensor inputs (real or synthetic) in testing with a more efficient surrogate model operating on lower-fidelity inputs, as in the embodiments described below.

Note, the existing and substitute upstream processing components are interchangeable in so far as they provide the same form of outputs; they may or may not operate on the same form of inputs in general. In the aforementioned testing example, the perception component and surrogate model operate on different forms of input (higher and lower fidelity inputs respectively).

Another context is AV stack design/refinement, where the aim might be to improve a stack by replacing an existing upstream component with a substitute component that is improved in the sense of being faster, more efficient and/or more reliable etc., but without materially altering downstream performance (here, the aim would be to maintain an existing level of downstream performance within the stack, but with improved speed, efficiency and/or reliability of the upstream processing). In this case, the existing and substitute components may operate on the same form of inputs, as well as providing the same form of outputs (e.g. the existing and surrogate upstream components may be alternative perception components, both of which operate on high-fidelity sensor inputs).

In embodiments, the ground truth outputs may be obtained from real inputs via manual annotation, using offline processing, or a combination thereof. Alternatively, the ground truth outputs may be simulated, e.g. the ground truth outputs may be derived from a ground truth state of a simulated driving scenario computed in a simulator.

As indicated, the method of the second aspect facilitates an indirect comparison of the existing upstream processing component and the substitute upstream processing component, on some downstream metric (i.e. in terms of the relative performance of the downstream processing component, relative to the ground truth). In this case, similarity may be assessed in terms of whether downstream performance of the existing upstream processing relative to the ground truth is similar to downstream performance of the substitute upstream processing component relative to ground truth.

In embodiments, an overall numerical performance score metric may be derived from the first and second numerical performance scores, indicating an extent of difference between the first and second numerical performance scores.

The methods allow upstream processing components (e.g., object detectors or other perception components/systems) to be systematically compared in terms of downstream performance (e.g. planner performance).

In embodiments of either aspect, the method may comprise outputting the numerical performance score, the first numerical performance score, the second numerical performance and/or the overall numerical performance score at a graphical user interface (GUI). For example, the GUI may allow driving performance to be evaluated and visualized in different driving scenarios. Numerical performance score(s) obtained using the methods herein may be displayed within a view of the GUI. A visualization component may be provided for rendering the graphical user interface (GUI) on a display system accessible to a user.

The substitute upstream processing component may be a surrogate model designed to approximate the existing upstream processing component, but constructed so as to operate on lower-fidelity inputs than the existing upstream processing component.

The surrogate model may be used to obtain the second set of upstream outputs for the first set of inputs by applying the surrogate model to a second set of upstream inputs of lower fidelity than the first set of upstream inputs, the first and second sets of upstream inputs pertaining to a common driving scenario or scene.

A surrogate model may be used to test the performance autonomous driving system based on low-fidelity simulation, in which the upstream processing component is replaced with the surrogate. Before conducting such testing, it is important to be confident that the surrogate is an adequate substitute, though downstream metric-based evaluation.

In performing such testing, performance issue in the autonomous driving system may be identified and mitigated via a modification to the autonomous driving system (though an appropriate modification to the autonomous driving system).

Alternatively, the upstream processing component and the substitute upstream processing component may operate on the same form of inputs.

For example, both upstream processing components may be of equally high fidelity, and the method may be used to compare their performance in terms of downstream task performance. For example, the upstream processing components could be alternative perception systems, and the method could be applied to assess their similarity in terms of downstream performance.

As another example, both upstream processing components may be surrogate models that operate on low-fidelity inputs. In this case, the method could be used to compare two candidate surrogate models.

The downstream processing component may be a planning system and each set of downstream outputs may be a sequence of spatial and motion states of a planned or realized trajectory, or a distribution over planned/realized trajectories.

In that case, the existing upstream processing component may, for example, comprise a perception component or a prediction component.

The downstream processing component may be prediction system and each set of downstream outputs may comprise a trajectory prediction.

In that case, the existing upstream processing component may, for example, comprise a perception component.

Further aspects herein provide a computer system comprising one or more computers configured to implement any of the above methods, and computer program code for programming a computer system to implement the same.

Certain embodiments will now be described, by way of example only, and with reference to the following schematic figures, in which:

### BRIEF DESCRIPTION OF FIGURES

FIG. 1 shows a schematic block diagram of a surrogate-based AV testing architecture;

FIGS. 2, 3 and 4 show plots of experimental results obtained using the methodology described below;

FIG. 5 shows an example neural network architecture for a surrogate model;

FIGS. 6, 7, 8, 9 10 and 11 show further experimental results;

FIG. 12 shows example surrogate and detector outputs, with a corresponding ground truth scene;

FIG. 13 shows a schematic function block diagram of an autonomous vehicle stack;

FIG. 14 shows a schematic overview of an autonomous vehicle testing paradigm;

FIG. 15 shows a schematic block diagram of a scenario extraction pipeline;

FIG. 16 shows a schematic block diagram of a testing pipeline;

FIG. 17 shows further details of a possible implementation of the testing pipeline.

### DETAILED DESCRIPTION

Embodiments are described below in the example context of perception evaluation, to facilitate efficient evaluation of complex perception tasks in simulation.

The described approach uses a novel form of downstream metric-based comparison to assess the suitability of a surrogate model in large scale testing. Details of the downstream metrics, and their application, are described below. First, a testing framework utilizing surrogate models is described in detail, in Sections 1 and 2 of the description. The downstream metric-based comparison is described in Section 4.

As noted, the downstream-metric based performance testing described herein has additional applications, and further examples are described towards the end of the description.

### 1. Overview of Surrogate-Based Testing Architecture

There has been increasing interest in characterising the error behaviour of deep learning models before deploying them into any safety-critical scenario. However, characterising such behaviour usually requires large-scale testing of the model that, in itself, can be extremely computationally expensive for a variety of real-world complex tasks, for example, tasks involving compute intensive object detectors as one of their components. The describe approach enables efficient large-scale testing of such tasks, so that the full potential of resources that can provide abundance of annotated data (such as simulators) can be utilised. This approach uses an efficient surrogate corresponding to the compute intensive components of the task under testing. The efficacy the methodology is demonstrated by evaluating the performance of an autonomous driving task in Carla [6] simulator with reduced computational expense (the results presented herein have been obtained by training efficient surrogate models for PIXOR [36] and Centerpoint LiDAR detectors), whilst demonstrating that the accuracy of the simulation is maintained.

Recent deep learning models have been shown to provide extremely promising results in a variety of real-world applications [13]. However, the fact that these models are vulnerable to diverse situations such as, shift in data distribution and additive perturbations [8, 12, 20, 33], has limited their practical usability in safety-critical situations such as driverless cars. A solution to this problem is to collect and annotate a large diverse dataset that captures all possible scenarios for training and testing. However, since the costs involved in manually annotating such a large quantity of data can be prohibitive, it might be beneficial to employ high-fidelity simulators to potentially produce infinitely many diverse scenarios with exact ground-truth annotations at almost no cost.

Although a simulator is a source of abundant annotated samples, in practice, it would be desirable to be able to use these samples to perform extensive testing of a given backbone model on a downstream task. This will allow us to find failure modes of such models before deployment. For example, let us assume that our objective is to find failure modes of a path planner (downstream task g) of a driverless car that takes detected objects as an input from a trained object detector (backbone-model ƒ); a common architecture in industrial production systems [5, 13]. Since the failure modes of the detector would have significant impact on the planner, it would be desirable to test the planner by giving inputs directly to the detector [31, 1]. Under this setting, one might want to use all possible high-fidelity synthetic generations x from the simulator as an input to the detector to characterize the failure modes of the planner. However, given that the inference of a practically useful object detector where the input is high-fidelity synthetic data itself is a computationally demanding operation [32], such an approach will not be scalable enough to perform extensive testing of the task.

One aim herein is to provide an efficient alternative to testing with a high-fidelity simulator and thereby enable large-scale testing. The described approach replaces the computationally demanding backbone model ƒ with an efficient surrogate \tilde{ƒ} that is trained to mimic the behaviour of the backbone model. As opposed to ƒ where the input is a high-fidelity sample x, the input to the surrogate is a much lower-dimensional ‘salient’ variable \tilde{s}. In the example of the object detector and path planner: x might be a high-fidelity simulation of the output of camera or LiDAR sensors, whereas s might be simply the position and orientation of other agents (e.g. vehicles and/or pedestrians) in the scene together with other aspects of the scene like the level of lighting which could also affect the results of the detection function ƒ. The training of the surrogate is performed to provide the following approximate composite model

$$g ( \tilde{f} ( \tilde{s} ) ) \approx g ( f ( x ) ) .$$

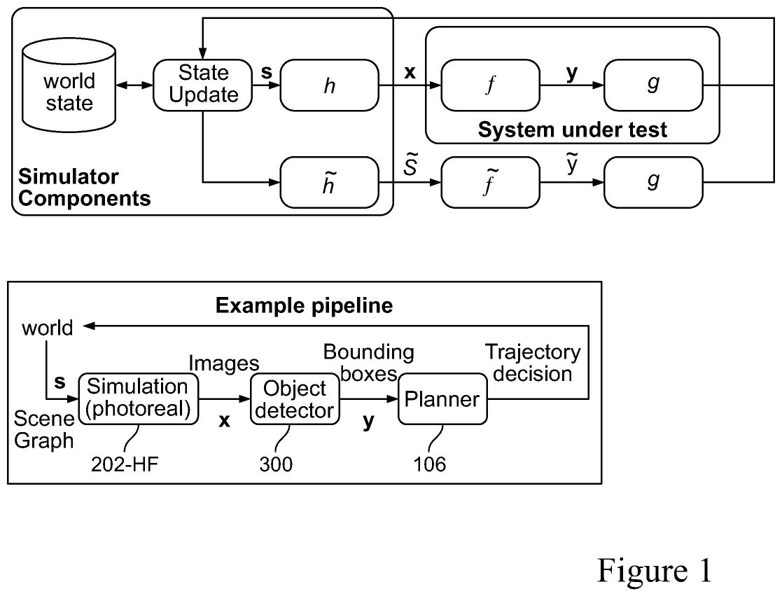

This allows rigorous testing of the downstream task to be performed efficiently using very low-dimensional inputs to an efficient surrogate model, as shown in FIG. 1.

FIG. 1 is a schematic diagram to show how an ‘expensive’ high-fidelity simulator, h, and backbone task ƒ can be circumvented during end-to-end testing with a surrogate model \tilde{ƒ}. Outputs \tilde{y} of the surrogate model \tilde{ƒ} are fed into the model for a downstream task g in the same way as outputs y of the backbone task ƒ would be, because those respective outputs, y and \tilde{y}, are the elements of the same vector space. A world state s is updated based on the output of the downstream task g. The world state s would be used by the high-fidelity simulator h to produce high-fidelity sensor readings x fed to the backbone task ƒ. Instead, an efficient low-fidelity simulator \tilde{h} is used to produce low-dimensional inputs, \tilde{s}, to the surrogate model \tilde{ƒ} (the world state s is updated in the same way based on the output of the downstream task g; the difference being that the outputs of the downstream task g are now dependent on the outputs \tilde{y} of the surrogate \tilde{ƒ}, as opposed to outputs y of the backbone ƒ).

For example, the high-fidelity simulator \tilde{h} may be a photorealistic or senor-realistic 202-HF, the backbone task ƒ may be an object detector 300 and the downstream task g may be a trajectory planner 106 (or prediction and planning system) that plans an ego trajectory for a mobile robot in dependence on the object detector outputs.

We (the applicant) have conducted extensive experiments to demonstrate the efficacy of the described approach to enable efficient large-scale testing of complex tasks. Results of large-scale experiments using the Carla [6] simulator for an adaptive cruise control task are presented herein, with surrogate models of two well-known LiDAR detectors, PIXOR [36] and Centerpoint [37] as the backbone model. The results demonstrate that the described approach approach is closest to the backbone task compared to baselines evaluated on several metrics, and yields a 20 times reduction in compute time.

### 2. Methodology

Expanding on the description of FIG. 1, training and testing a model for a complex task primarily involves the following three modules—(1) a data generator (h) that provides the high-fidelity sensory input domain X; (2) a backbone-task (ƒ_{θ}), parameterized by θ, that maps x∈X into an intermediate representation y∈ [symbol] ; and (3) a downstream task (g_{φ}), parameterized by φ, that takes the intermediate y as an input and maps it into a desired output z∈ [symbol] . For example, devising a path planner that takes as input the raw sensory data x from the world via sampler h and outputs an optimal trajectory would rely on intermediate solutions such as accurate detections ƒ_{θ}(x) by an object detector ƒ (backbone task) in order to provide the optimal trajectory g_{φ}(ƒ_{θ}(x)). Most real-world problems include of such complex tasks that heavily depend on intermediate solutions, obtaining which can sometimes be the main bottleneck from both efficiency and accuracy points of view.

Considering, the same example of a path planner, an object detector is computationally expensive in real-time. Therefore, extensively evaluating the planner that depends on the detector can quickly become computationally infeasible as there exist millions of road scenarios over which the planner should be tested before deployment into any safety-critical environment such as driverless cars in the real-world.

Two bottlenecks of evaluating extensively such complex tasks are considered: (1) efficiently obtaining all possible test scenarios; and (2) efficient inference of the intermediate expensive backbone tasks. Though simulators, as used in this work, can theoretically solve the first problem as they can provide infinitely many test scenarios, their use, in practice, is limited as it still is very expensive for the backbone task ƒ to process these high-fidelity samples obtained from the simulator, and for the simulator to generate these samples.

A solution to alleviate these bottlenecks is described. Instead of obtaining high-fidelity samples from the simulator h we generate low-dimensional samples making sure that these embeddings summarise the crucial information required by the backbone task ƒ to be able to provide accurate predictions. Using these low-dimensional simulator outputs, an efficient and relatively simple model can be trained to mimic the behaviour of the target backbone model ƒ which provides the input for the downstream task g under test. This will allow very fast and efficient evaluation of the downstream task by approximating the inference of the backbone model using a surrogate model. Details of these approximations are described below.

Obtaining Low-fidelity Simulation Data: In the case of simulators, the data generation process can be written as a mapping h: s [symbol] x, where s∈ [symbol] denotes the world-state that is normally structured as a scene graph. Note, for high-fidelity generations, s is very high dimensional as it contains all the properties of the world necessary to generate a realistic sensor reading x. For example, in the case of road scenarios, it typically contains, but is not limited to, positions and types of all vehicles, pedestrians and other moving objects in the world, details of the road shapes and surfaces, surrounding buildings, light and RADAR reflectivity of all surfaces in the simulation, and also lighting and weather conditions [6]. There is usually a trade-off between an accurate simulator and the computational expense of the simulator, so even if a high fidelity simulator is available, it may be intractable to produce sufficient simulated data for training and evaluation as the mapping h in itself is expensive. Noting that a low-fidelity simulator \tilde{h}: s [symbol] \tilde{s}(\tilde{h}) can be created to map high-dimensional s into low-dimensional ‘salient’ variables s∈ [symbol] for a variety of tasks [28], \tilde{s} is as an input to the surrogate backbone task (further details on the design of the surrogate are described below). In the simplest case, the mapping \tilde{h}(·) could consist of a subsetting operation. For example, in object detectors, \tilde{h} could output s that contains the position and size of all the actors in the scene. In order to provide more useful information in \tilde{s}, low-fidelity physical simulations may be included in \tilde{h}. For example, a ray tracing algorithm may be used in \tilde{h} to calculate geometric properties such as occlusion of actors in the scene for one of the ego vehicle's sensors.

The subsetting operation and deciding what physical simulations to include in \tilde{h} utilizes domain information and knowledge about the backbone task. This is a reasonable assumption for most of the perception related tasks of interest, as engineers have a good intuition of what factors are necessary to capture the underlying performance. A more generic setting to automatically learn \tilde{h} is also envisaged.

Efficient Surrogate for the Backbone Model: The next step is to use the low-dimensional \tilde{s} in order to provide reliable inputs for the downstream task. Recall, the objective is to provide an efficient way to mimic ƒ_{θ}(h(s)) so that its output can be passed to the downstream task for large-scale testing (refer FIG. 1). To this end, using the low-dimensional \tilde{s} as input, we design and train a surrogate function \tilde{ƒ}_{θ} such that \tilde{ƒ}_{θ}(\tilde{s})≈ƒ_{θ}(h(s)), for all s∈ [symbol] . By design, the surrogate function takes a very low-dimensional input compared to the high-fidelity x and, as demonstrated in the experimental results, is orders of magnitude faster than operating a high-fidelity simulator, h, and the original backbone function, ƒ.

Details of the surrogate model are now described. As mentioned, the selection of the salient variables \tilde{s} and the form of the surrogate function is a design choice that utilized domain knowledge. An example context considered herein involves large-scale testing of a planner that requires an object detector as the backbone task. Here, a suitable choice of salient variables for the input to the detector surrogate involves: position, linear velocity, angular velocity, actor category, actor size, and occlusion percentage (the results below specify which variables were used in which experiments). Note, additional and/or alternative salient variables could be used. To compute the occlusion percentage efficiently, a low-resolution semantic LiDAR is simulated and the proportion of rays terminating in the desired agent's bounding box are calculated [35]. Typically, these salient variables are available at no computational cost when the simulator updates the world-state, or can be easily obtained with relatively inexpensive supplementary calculations.

The surrogate \tilde{ƒ}_{θ} for the object detector 300 is implemented, in the following examples, as simple probabilistic neural network

$${\tilde{f}}_{\tilde{θ}} : \tilde{\underline{s}} ↦ y$$

To train \tilde{ƒ}, for every s, a tuple {\tilde{s}=h(s), y=ƒ(h(s))} of input-output is created for every frame, which we process to obtain an input-output tuple for each agent in the scene. For example, the Hungarian algorithm with an intersection over union cost between objects [9] may be used to associate the ground-truth locations and the detections from the original backbone model, ƒ, on a per-frame basis, yielding training data for the surrogate detector in the form [symbol] ={\tilde{s}ⁱ, \tilde{y}ⁱ}ᵢ₌₁^{k}, and although \tilde{ƒ} is notionally defined as a function of all objects in the scene, the described implementation factorises over each agent in the scene and acts on a single agent basis. A suitable network architecture for the surrogate is a multi-layered fully-connected network with skip connections, and dropout layers between ‘skip blocks’ (similar to a ResNet [10]), which is shown in the Annex A. The final layer of the network outputs the parameters of the underlying probability distributions, which normally is a Gaussian distribution (mean and log standard deviation) for the detected position of the objects, and a Bernoulli distribution for the binary valued outputs, e.g. whether the agent was detected [18]. The training is performed by maximizing the following expected log-likelihood:

$${ℒ}_{total} = {\sum }_{i} log p ( {\tilde{y}}_{det}^{i} \vert {\tilde{s}}^{i} ) + {\{ {y}_{det}^{i} = 1 \}}_{} log p ( {\tilde{y}}_{pos}^{i} \vert {\tilde{s}}^{i} ) , \qquad ( 1 )$$

where, associated with the surrogate function \tilde{ƒ}_{θ}(·), p(·|\tilde{s}ⁱ) represents the likelihood, \tilde{y}_{det} represents the Boolean output which is true if the object was detected, and \tilde{y}ₚₒₛ represents a real-valued output describing the centre position of the detected object, respectively. The term

$$log p ( {\tilde{y}}_{det}^{i} \vert {\tilde{s}}^{i} )$$

in Eqn. 1 is equivalent to the binary cross-entropy when using a Bernoulli distribution to predict false negatives. Assuming Cartesian components of the positional error to be independent, this term may be determined as:

$$log p ( {\tilde{y}}_{pos}^{i} \vert {\tilde{s}}^{i} ) = log ( ( {\tilde{y}}_{x , pos}^{( i )} ; {μ}_{x} , {σ}_{x} ) \cdot ( {\tilde{y}}_{y , pos}^{( i )} ; {μ}_{y} , {σ}_{y} ) ) = \frac{{( {\tilde{y}}_{x , p o s}^{( i )} - {μ}_{x} )}^{2}}{2 {σ}_{x}^{2}} + \frac{{( {\tilde{y}}_{y pos}^{( i )} - {μ}_{y} )}^{2}}{2 {σ}_{y}^{2}} + log {σ}_{x} {σ}_{y} \qquad ( 2 )$$

where μ and log (σ) are the outputs of the fully connected neural network. Further details may be found in Kendall and Gal [16] and Kendall et al. [17].
3. Comparison with Existing Methods:

End-to-end evaluation refers to the concept of evaluating components of a modular machine learning pipeline together in order to understand the performance of the system as a whole. Such approaches often focus on strategies to obtain equivalent performance using a lower fidelity simulator whilst maintaining accuracy to make the simulation more scalable [28, 3, 7]. Similarly, Wang et al. [34] use a realistic LiDAR simulator to modify real-world LiDAR data which can then be used to search for adversarial traffic scenarios to test end-to-end autonomous driving systems. Kadian et al. [15] attempt to validate a simulation environment by showing that an end-to-end point navigation network behaves similarly in the simulation to in the real-world by using the correlation coefficient of several metrics in the real-world and the simulation. End-to-end testing is possible without a simulator, for example Philion et al. [25] evaluate the difference between planned vehicle trajectories when planning using ground truth and a perception system and show that this enables important failure modes of the perception system to be identified.

The approach described herein differs from these in that the surrogate model methodology enables end-to-end evaluation without running the backbone model in the simulation.

Perception error models (PEMs): Perception Error Models (PEMs) are used in simulation to replicate the outputs of perception systems so that downstream tasks can be evaluated as realistically as possible. Piazzoni et al. [27] present a PEM for the pose and class of dynamic objects, where the error distribution is conditioned on the weather variables, and use the model to validate an autonomous vehicle system in simulation on urban driving tasks.

Piazzoni et al. [26] describe a similar approach using a time dependent model and a model for false negative detections. Time dependent perception PEMs have also been used by Berkhahn et al. [4] to model traffic intersections with a behaviour model and a stochastic process misperception model on velocity, and Hirsenkorn et al. [11] by creating a Kernel Density Estimator model of a filtered radar sensor, where the simulated sensor is modelled by a Markov process. Zee et al. [38] propose to model an off the shelf perception system using a Hidden Markov Model. Modern machine learning techniques have also been used to create PEMs, for example Krajewski et al. [18] create a probabilistic neural network model for a LiDAR sensor, Arnelid et al. [2] use Recurrent Conditional Generative Adversarial Networks to model the output of a fused camera and radar sensor system, and Suhre and Malik [30] describe an approach for simulating a radar sensor using conditional variational auto-encoders.

By contrast, herein a more general framework for the training of surrogate models in a modern probabilistic machine learning context with a large-scale evaluation is described.

Moreover, as noted, the described approach also uses a novel form of downstream metric-based comparison to assess the suitability of a surrogate model.

### 4. Assessing Surrogate Suitability

As described in the Metrics subsection below, the suitability of a surrogate model may be rigorously assessed using a downstream-metric-based comparison (in the examples described below, this is supported by additional comparison using standard classification/regression metrics). This section also includes the applicant's experimental results, a subset of which have been generated using the downstream-metric-based comparison described herein.

Overview: In the experiments, the Carla simulator [6] was used to analyze the behaviour of an agent in two driving tasks g; (1) adaptive cruise control (ACC) and (2) the Carla leader board. The agent uses a LiDAR object detector ƒ to detect other agents and make plans accordingly. Using the methodology described in Section 2, we construct a Neural Surrogate (NS) model \tilde{ƒ} (\tilde{ƒ}) that, as opposed to f, does not depend on high-fidelity simulated LiDAR scans. The Carla configuration is provided in Annex C. We show that the surrogate agent behaves similarly to the real agent while being extremely efficient.

### Details of Driving Scenarios:

1. Adaptive Cruise Control (ACC): The agent follows a fast moving vehicle. Suddenly, the fast moving vehicle cuts out into an adjacent lane, revealing a parked car. The agent must brake to avoid a collision.
2. Carla Leaderboard: See Ros et al. [29] for details. This contains a far more diverse set of driving scenarios, including urban and highway driving, and is approximately a two orders of magnitude increase in the total driving time relative to the ACC task. Therefore this evaluation can be seen as a larger scale evaluation of our methodology.

For the ACC task we use a simple planner described in Section 4.1 that maintains a constant speed and brakes to avoid obstacles. For the more demanding Carla Leaderboard we use a more robust planner and detector, described in detail in Section 4.2. Baselines: We compare our approach Neural Surrogate (NS) against three strong baseline surrogate models (\tilde{ƒ}):
Planning using ground truth (GT) locations of agents, which are available from \tilde{s} (\tilde{s}).
A logistic regression (LR) surrogate is trained to predict the false negatives (missed detections) of the backbone model ƒ for a given \tilde{s}. Note, \tilde{s} here is same as the salient variables used in NS. The logits for the true class probability are then predicted by first passing the input via a linear mapping W and then applying a sigmoid function, i.e. pₜ=σ(W\tilde{s}) where σ is the sigmoid function [22]. The model is trained using the focal loss,

$$ℒ ( {p}_{t} ) = - {{α}_{t} ( 1 - {p}_{t} )}^{γ} log ( {p}_{t} )$$

where pₜ represents the true class probability and αₜ=α for the true class and αₜ=1−α for the negative class, in order to account for class imbalance [19]. The hyperparameters used for the focal loss were manually tuned to be α=0.6 and γ=2 via cross-validation over the classification metrics. Once a box has been identified as a true-positive detection of ƒ by the LR model, its exact co-ordinates from \tilde{s} are then passed to the planner.
A Gaussian Fuzzer (GF) is a simple surrogate model where the exact position and velocity of a box obtained from \tilde{s} are simply perturbed with samples from independent Gaussian and StudentT distributions respectively (StudentT distributions are used due to the heavy tails of the detected velocity errors). This is Eqn. 2 with fixed μ and σ, i.e. not a function of other variables in \tilde{s}. These parameters are obtained analytically using Maximum Likelihood Estimation (MLE). For example, for the Gaussian distribution over positional errors, the MLE solution is simply the empirical mean and the standard deviation of the detection position errors which is obtained using the train set.

In the Carla leaderboard evaluation only a ground truth baseline is used. The hyperparameters used for the training of all the surrogate models are shown in Annex B.

Surrogate Training Data: In both experiments the Carla leaderboard scenarios are used to obtain training data for surrogate models and the LiDAR detector.
1. In the first experiment, scenarios 0-9 are used for training and scenario 10 is used for testing. Pedestrians are excluded from the data because the ACC task does not involve pedestrians.
2. The second experiment contains a wider variety of driving scenarios so the collected dataset is larger; scenarios 0-58 are used for training and scenarios 59-62 are used for testing.

### Metrics:

Common classification and regression metrics to directly compare the outputs of the surrogate model and the real model on the backbone task:
Precision and recall.
Classification accuracy.
Sampled position mean squared error (spMSE): the mean squared error of the detections y or surrogate predictions \tilde{y} (\tilde{y}), as appropriate, relative to the ground truth values in s.
Negative log predictive density (NLPD) of the ground truth according to the surrogate model's distribution.

In the present context, the aim is to quantify (1) how closely the surrogate mimics the backbone model f; and (2) how close it is to the ground-truth obtained from \tilde{s}. Note, while evaluating a surrogate model relative to ƒ a false negative of \tilde{ƒ} would be a situation when it predicts that an agent will be detected by ƒ while it was in fact missed; conversely evaluating a surrogate model relative to the ground truth means that a false negative of \tilde{ƒ} would be when an agent is not detected by \tilde{ƒ} while it is in fact present in the ground truth data. When evaluating surrogate models relative to the detector (comparing y to \tilde{y}), the best surrogate is the one with the highest value of the evaluation metric. However, when evaluating surrogate models relative to the ground truth (comparing y or \tilde{y}, as appropriate, to s), the best surrogate is the one whose score is closest to the detector's score.

In the following examples, the metrics are only evaluated for objects within 50 m of the ego vehicle, since objects further than this are unlikely to influence the ego vehicle's behaviour.

This is merely one possible design choice and different choices may be made depending on the context.

In addition, downstream metrics are used to compare the performance of the surrogate and real agents on a downstream task. For the ACC task, the runtime per frame (with and without h/\tilde{h}), Maximum Braking Amplitude (MBA), and MBA timestamp are evaluated. MBA quantifies the degree to which the braking was applied relative to the maximum possible braking. The mean Euclidian norm (meanEucl) is also evaluated, defined as the time integrated norm of the stated quantity, i.e. to compare variables v₁(t) and v₂(t), the metric is

$$\frac{1}{{t}^{′}} {\int }_{t = 0}^{t = {t}^{′}} {‖ {v}_{1} ( t ) - {v}_{2} ( t ) ‖}_{2} dt , \qquad ( 3 )$$

though in practice a discretised sum is used. This metric is a natural, time dependent, method of comparing trajectories in Euclidean space. In Annex E, a relationship is provided between Eqn. 3, and the planner KL-divergence metric proposed by Philion et al. [25].

The maximum Euclidian norm (maxEucl) is also computed to show the maximum instantaneous difference in the stated quantity, which is given by max

$${max}_{t ∈ [ 0 , {t}^{′} ]} {‖ {v}_{1} ( t ) - {v}_{2} ( t ) ‖}_{2} . \qquad ( 4 )$$

In the Carla leaderboard task for the detector and surrogate, the standard metrics used for Carla leaderboard evaluation, i.e. route completion, pedestrian collisions and vehicle collisions, are compared. The cumulative distribution functions of the time between collisions for the detector, surrogate, and ground truth are also computed.

### 4.1. Carla Adaptive Cruise Control Task

### Configuration Details:

In this experiment, our backbone model ƒ consists of a PIXOR LiDAR detector trained on simulated LiDAR pointclouds from Carla [36], followed by a Kalman filter which enables the calculation of the velocity of objects detected by the LiDAR detector. Therefore y and \tilde{y} consist of position, velocity, agent size and a binary valued variable representing detection of the object. To simplify the surrogate model, in this particular experiment, we assume that the ground-truth value of the agent size can be used by the planner whenever required. The salient variables \tilde{s} consist of position, orientation, velocity, angular velocity, object extent, and percentage occlusion. The downstream task consists of a planner which is shown in further detail in Annex D. The planner accelerates ego to a maximum velocity unless a slow moving vehicle is detected in the same lane as ego, in which case ego will attempt to decelerate so that ego's velocity matches that of the slow moving vehicle. If the ego is closer than 0.1 metres to the slow moving vehicle then it applies emergency braking.

Results: Regression and classification performance relative to the ground-truth on the train and test set are shown in Table 1 for both the surrogate models and the detector.

TABLE 1
Metrics comparing surrogate models \tilde{f} (LR, NS, and GF), and the Pixor
detector (the backbone model f) on the train and test set relative to
the ground-truth. The surrogate closest to the detector is shown
in bold. Note that all the surrogate models trivially achieve a
precision of 1 as they do not model false positives.

| | NS (our) | GF | LR | Detector |
|---|---|---|---|---|
| | Train Set | | | |
| Precision | 1 | 1 | 1 | 0.934 |
| Recall | 0.642 | 1 | 0.218 | 0.614 |
| spMSE | 0.231 | 0.294 | 0 | 0.239 |
| | Test Set | | | |
| Precision | 1 | 1 | 1 | 0.842 |
| Recall | 0.533 | 1 | 0.238 | 0.476 |
| spMSE | 0.267 | 0.295 | 0 | 0.273 |

Table 2 shows similar metrics to Table 1, but this time computed for the surrogate models relative to the detector. This shows that although the LR surrogate is predicting a similar proportion of missed detections, the NS is more effective at predicting these when the detector would also have missed the detection.

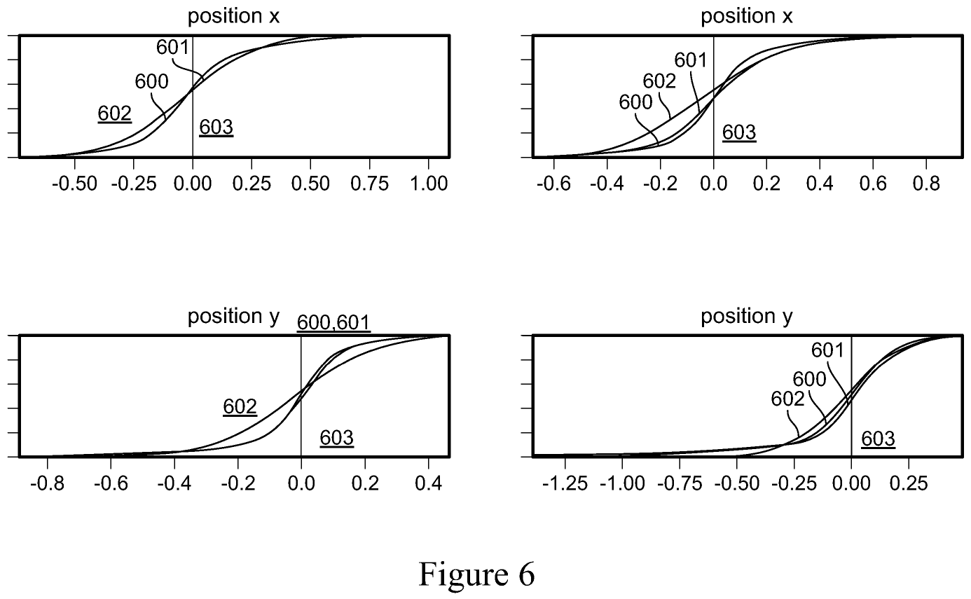

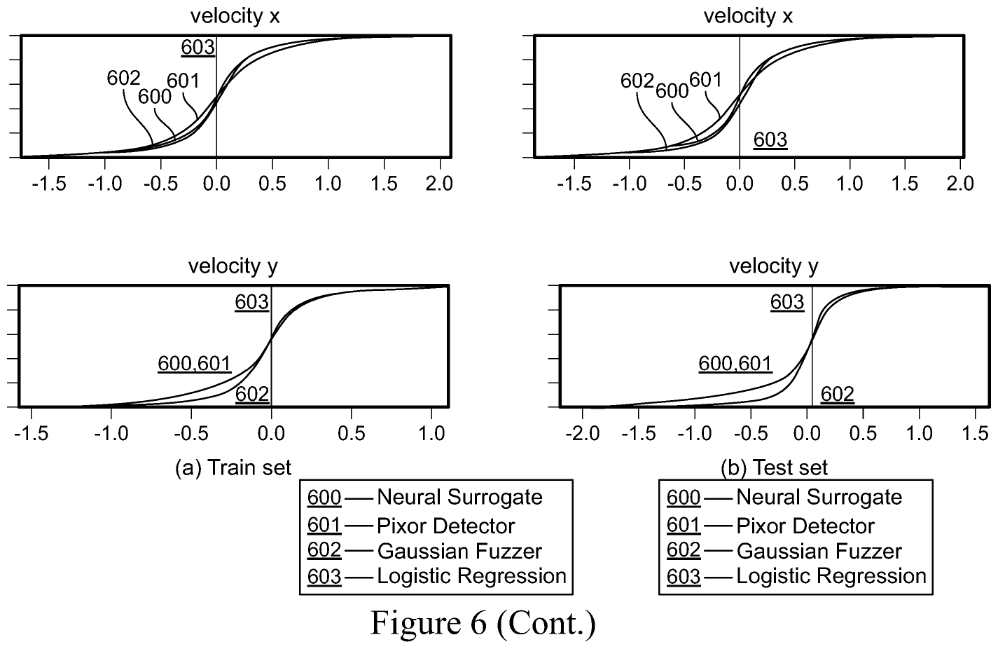

FIG. 6 contains plotted empirical cumulative distribution functions for the positional and velocity error predicted by each surrogate model and the true detector relative to the true object locations. The following reference signs are used in FIG. 6: neural network surrogate (600), PIXOR detector (601), Gaussian Fuzzer (602), Logistic Regression surrogate (603). Note that in all cases the Neural Surrogate distribution is closer than any of the other baselines to the distribution of the PIXOR Detector being approximated. Although the fit of the models to the training set appears similar from these plots, the performance of a planner downstream from these models is both visually and quantifiably different (see below).

TABLE 2
Metrics comparing LR, NS (our) and GF surrogate models on the train
and test set relative to the detector. Note that negative log predictive
density (NLPD) is not directly comparable between models, since
this loss is only suffered on the variables which the model predicts
with a probability distribution. The Gaussian Fuzzer trivially achieves
a recall of 1, since the detector does not model false negatives.

| | LR | GF | NS (our) |
|---|---|---|---|
| | Train Set | | |
| Accuracy ↑ | 0.688 | 0.244 | 0.954 |
| NLPD ↓ | 0.102 | 0.181 | −0.116 |
| Recall ↑ | 0.277 | 1 | 0.931 |
| Precision ↑ | 0.332 | 0.244 | 0.886 |
| | Test Set | | |
| Accuracy ↑ | 0.784 | 0.176 | 0.915 |
| NLPD ↓ | 0.096 | 0.221 | 0.434 |
| Recall ↑ | 0.412 | 1 | 0.823 |
| Precision ↑ | 0.392 | 0.176 | 0.730 |

In Table 3, we provide MBA and time efficiency results. We show that the surrogates indeed are multiple factor faster than the backbone model while showing MBA behaviour similar to the backbone model. Notably the wall-time taken per step (DTPF) is about 100 times higher for the PIXOR Detector than the surrogate models, not including the simulator rendering time, with all models running on an Intel Core i7-8750H CPU. When the simulator rendering time is included the difference is reduced to 20 times (TTPF), indicating that the majority of the time savings are realised by removing the object detector from the simulation pipeline. The total time per frame for GF is approximately 0.06 seconds less than for the other surrogate models since in this case the headless simulator \tilde{h} does not have to calculate the occlusion of agents.

TABLE 3
Results showing Timestamp of Maximum Braking Amplitude (tMBA),
Maximum Braking Amplitude (MBA), Detector time per frame for
f and \tilde{f} (not including the simulator rendering time) (DTPF),
Total Time Per Frame (TTPF) - including simulator time (h, \tilde{h}),
state update, and the planner time (g). For all metrics the most similar
model to the detector is shown in bold. All time noted in seconds.

| | Det. | GF | NS | LR | GT |
|---|---|---|---|---|---|
| tMBA | 13.5 | 19.0 | 13.5 | 15.8 | 19.9 |
| MBA | 1 | 0.378 | 1 | 0.518 | 0.093 |
| DTPF | 1.511 | 0.013 | 0.017 | 0.013 | 0.005 |
| TTPF | 1.644 | 0.023 | 0.087 | 0.083 | 0.022 |

In Table 4, a selection of pairwise metrics is shown comparing the ego trajectory in each simulation environment. The pairwise metrics show that using a surrogate model produces closer agent behaviour to the backbone model (LiDAR detector) compared to GT, both for metrics based on velocity and position. The NS is the best performing model on all pairwise metrics The GF produces similar ego trajectories to the GT baseline, and this is most likely because false negatives, which cause delayed braking and are therefore influential in this scenario, are not included in both cases. The metrics indicate that the LR model is most similar to the NS, however, the ego trajectories produced by the LR are less similar to those produced by the LiDAR detector than those produced by the NS.

Plots of the actors' trajectories are shown in FIGS. 6 to 11 for the ACC experiment.

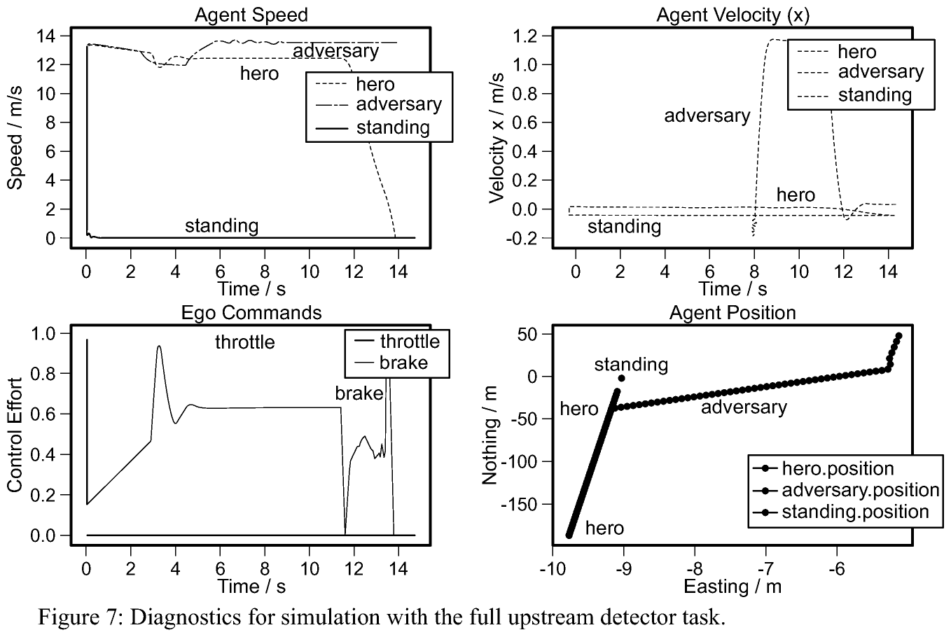

FIG. 7: Diagnostics for simulation with the full upstream detector task.

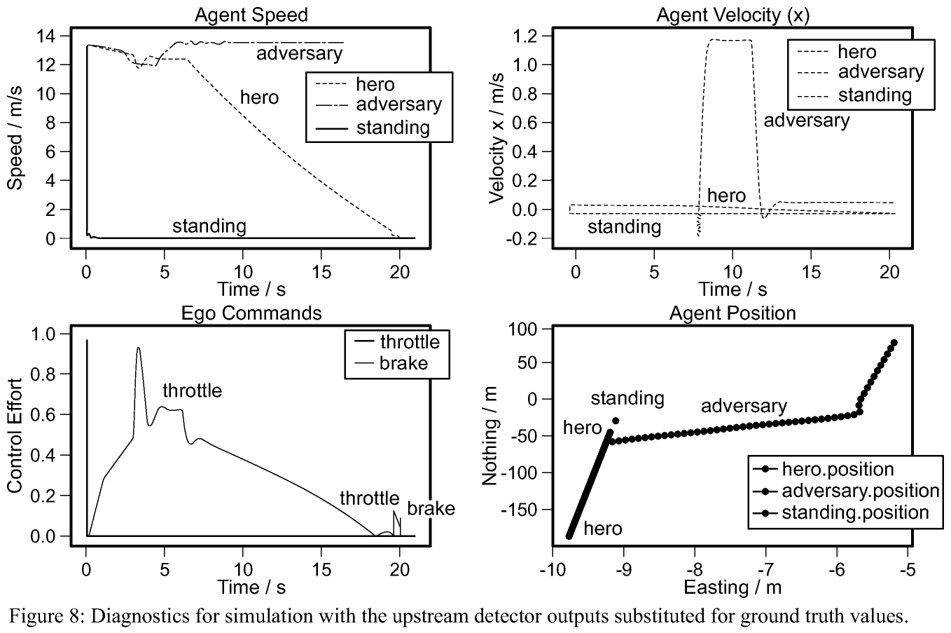

FIG. 8: Diagnostics for simulation with the upstream detector outputs substituted for ground truth values.

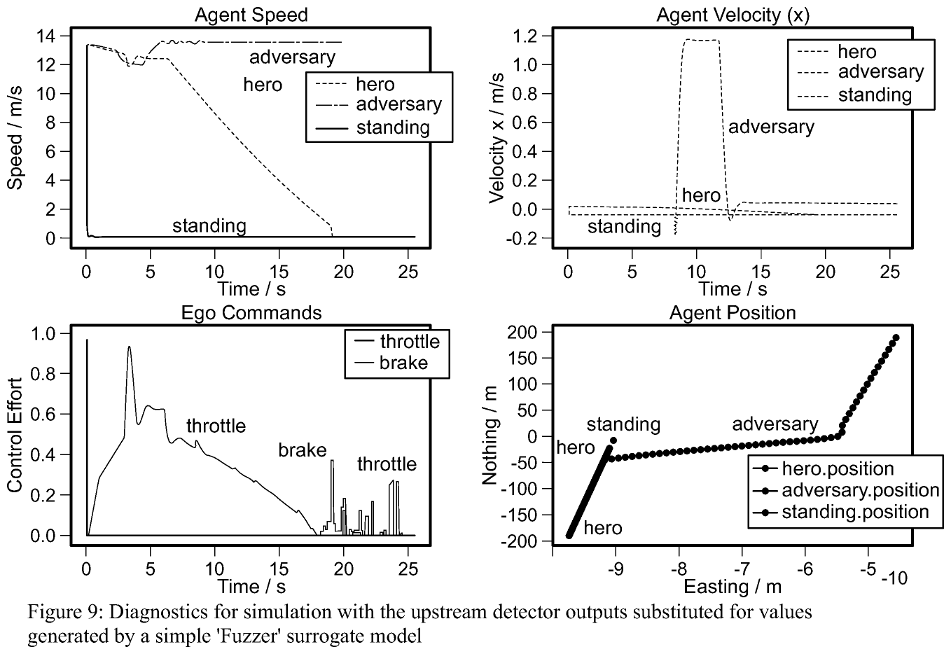

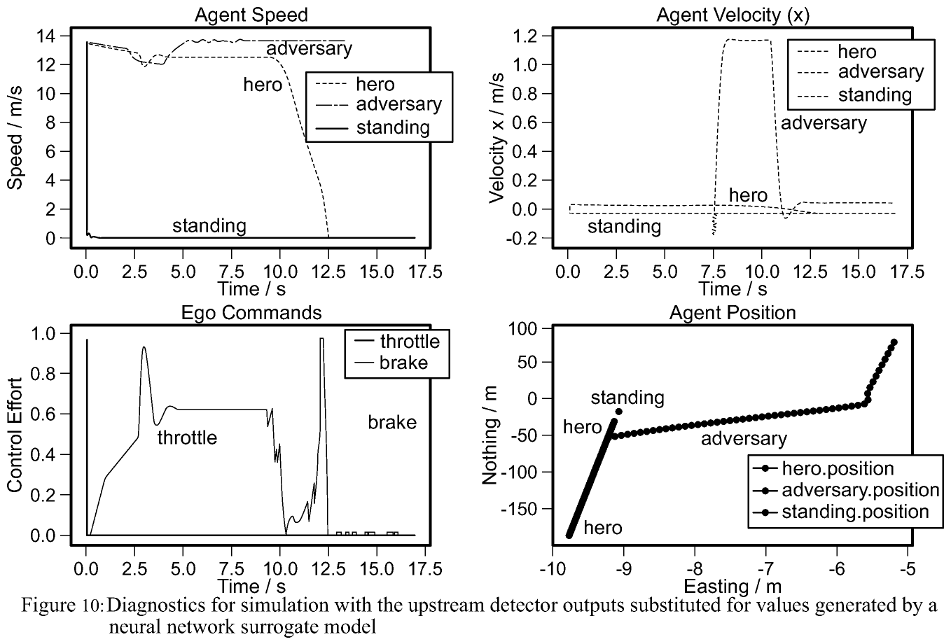

FIG. 9: Diagnostics for simulation with the upstream detector outputs substituted for values generated by a simple ‘Fuzzer’ surrogate model.

FIG. 10: Diagnostics for simulation with the upstream detector outputs substituted for values generated by a neural network.

FIG. 11: Diagnostics for simulation with the upstream detector outputs substituted for values generated by a logistic regression surrogate model surrogate model.

Note, the high degree of visual similarity between FIG. 7 (full upstream detector) and FIG. 10 (neural network surrogate). This is consistent with the performance results obtained with the downstream-metric based comparisons computed with Equations 3 and 4, supporting the usefulness of those metrics.

TABLE 4
Mean and Max Euclidean Norm of displacement comparing ego trajectory in different simulation environments, computed for the ego position
and velocity traces separately (Eqn. 3 and Eqn. 4). For both metrics the most similar model to the detector f is shown in bold. The
normalized value of the metric, obtained by dividing the metric by the ground truth - detector value, is shown in brackets.

| | Det. | GF | NS | | LR | | GT | | Det. | GF | | NS | | LR | | GT | |
|---|---|---|---|---|---|---|---|---|---|---|---|---|---|---|---|---|---|
| | meanEucl Position ↓ | | | | | | | | maxEucl Position ↓ | | | | | | | | |
| Det. | 0 (0.0) | 4.9 (0.98) | 0.40 | (0.08) | 1.6 | (0.32) | 4.9 | (1.0) | 0.0 (0.0) | 19 | (0.99) | 2.2 | (0.11) | 7.9 | (0.41) | 19 | (1.0) |
| GF | | 0 (0.0) | 4.5 | (0.92) | 4.1 | (0.83) | 0.15 | (0.03) | | 0.0 | (0.0) | 17. | (0.87) | 11. | (0.57) | 0.36 | (0.019) |
| NS | | | 0 | (0.0) | 1.2 | (0.24) | 4.6 | (0.93) | | | | 0.0 | (0.0) | 5.7 | (0.30) | 17. | (0.89) |
| LR | | | | | 0 | (0.0) | 4.2 | (0.85) | | | | | | 0.0 | (0.0) | 11. | (0.59) |
| GT | | | | | | | 0 | (0.0) | | | | | | | | 0.0 | (0.0) |
| | meanEucl Velocity ↓ | | | | | | | | maxEucl Velocity ↓ | | | | | | | | |
| Det. | 0 (0.0) | 1.5 (0.99) | 0.20 | (0.13) | 0.71 | (0.46) | 1.5 | (1.0) | 0.0 (0.0) | 5.5 | (0.99) | 2.0 | (0.35) | 4.1 | (0.73) | 5.5 | (1.0) |
| GF | | 0 (0.0) | 1.3 | (0.87) | 0.93 | (0.60) | 0.027 | (0.017) | | 0.0 | (0.0) | 4.7 | (0.84) | 3.4 | (0.61) | 0.11 | (0.019) |
| NS | | | 0 | (0.0) | 0.52 | (0.34) | 1.3 | (0.88) | | | | 0.0 | (0.0) | 3.2 | (0.57) | 4.7 | (0.85) |
| LR | | | | | 0 | (0.0) | 0.94 | (0.61) | | | | | | 0.0 | (0.0) | 3.4 | (0.62) |
| GT | | | | | | | 0 | (0.0) | | | | | | | | 0.0 | (0.0) |

### 4.2. Carla Leaderboard Evaluation Configuration

Details: In this experiment, the backbone model ƒ is a Centrepoint LiDAR detector for both vehicles and pedestrians, trained on the simulated data from Carla in addition to proprietary real-world data. The downstream planner g is a modified version of the BasicAgent included in the Carla Python API, where changes were made to improve the performance of the planner. The BasicAgent planner uses a PID controller to accelerate the vehicle to a maximum speed, and stops only if a vehicle within a semicircle of specific radius in front of ego is detected where the vehicle's centre is in the same lane as ego. We modified BasicAgent to avoid pedestrian collisions and brake when the corner of a vehicle is inside a rectangle of lane width in front of the ego such that the vehicle's lane is the same as one of ego's future lanes. Also, the BasicAgent was modified to drive slower close to junctions.

The NS model architecture is mostly the same as in Section 2, but the agent velocity is removed from y, since the BasicAgent does not require the velocities of other agents. In addition, an extra salient variable is provided to the network in \tilde{s}: a one hot encoding of the class of the ground truth object (vehicle or pedestrian) and in the case of the object being a vehicle, the make and model of the vehicle. Since the training dataset is imbalanced and contains more vehicles at large distances from the ego vehicle, minibatches for the training are created by using a stratified sampling strategy: the datapoints are weighted using the inverse frequency in a histogram over distance with 10 bins, resulting in a balanced distribution of vehicles over distances.

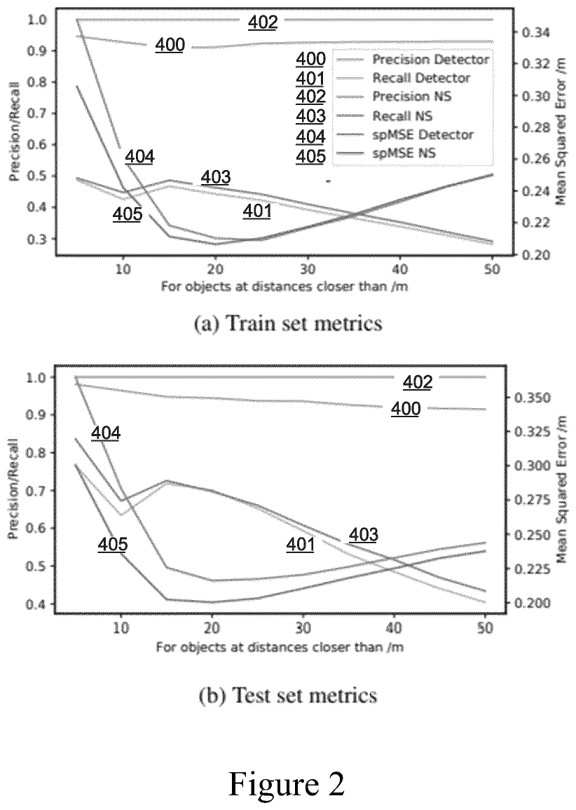

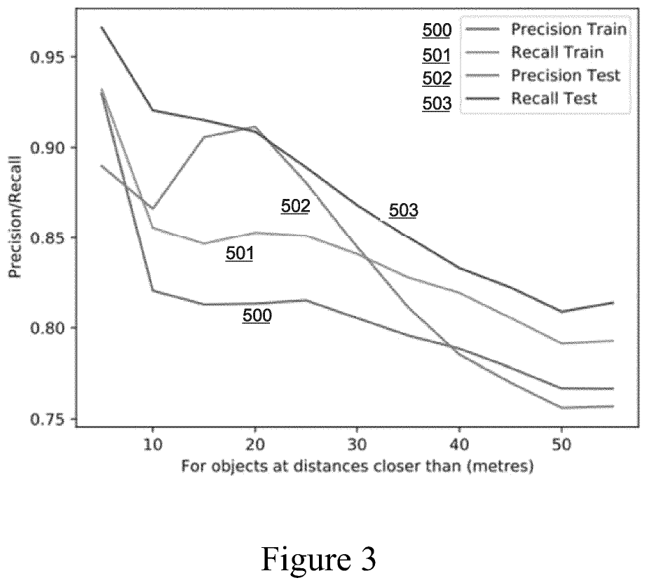

Results: Metrics on the train and test set relative to the ground-truth are shown in FIG. 2 for both the surrogate model and the detector. FIG. 3 shows similar metrics computed for the surrogate model relative to the detector. The negative log predictive density is −0.17 on the train set and −0.042 on the test set.

Metrics used for Carla leaderboard evaluation are summarised in Table 5. Since the NS does not model false positive detections, the route completion is lower in some scenarios where a false positive LiDAR detection of street furniture confuses the planner, which does not happen for the NS or the GT.

FIG. 2: Metrics comparing NS and the Centrepoint detector on train and test set relative to the ground-truth. The precision of NS is always 1 because, by design, it is unable to predict false positives. Notice that the NS closely mimics the behaviour of the Centrepoint detector with respect to these metrics.

Results are denoted using the following reference signs: precision detector (400), precision recall (410), precision NS (402), recall NS (403), spMSE detector (404) and spMSE NS (405).

FIG. 3: Metrics comparing NS on the train and test set relative to the detector. We see that the NS performs well on all metrics, particularly for objects at lower distances which are usually the most influential on the behaviour of ego.

Results are denoted using the following reference signs: precision train (500), recall train (501), precision test (502), and recall test (503).

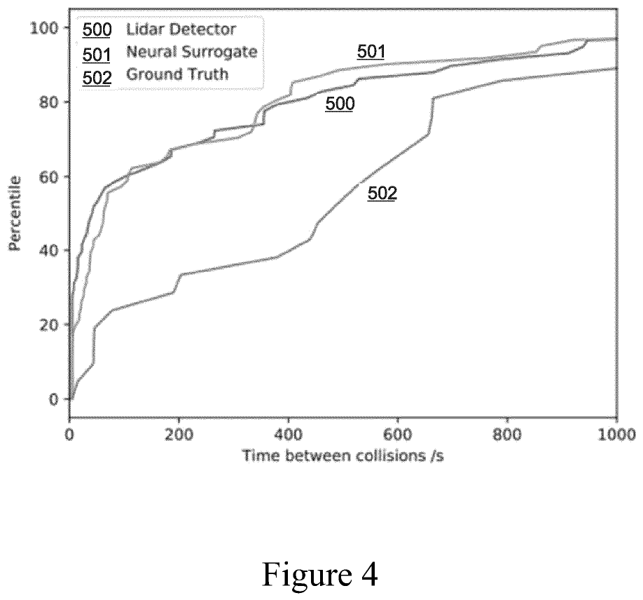

FIG. 4: Cumulative distribution of the time between collisions during the Carla leaderboard evaluation for NS, GT, and the Centrepoint detector. The NS captures the time between collisions for the Centrepoint model much more effectively than the GT, and at a fraction of the cost of running the high-fidelity simulator and the Centrepoint detector. Results are denoted using the following reference signs: lidar detector (600), natural surrogate (601), and ground truth (602).

In FIG. 4, NS is shown to be more similar to the LiDAR detector than the ground truth.

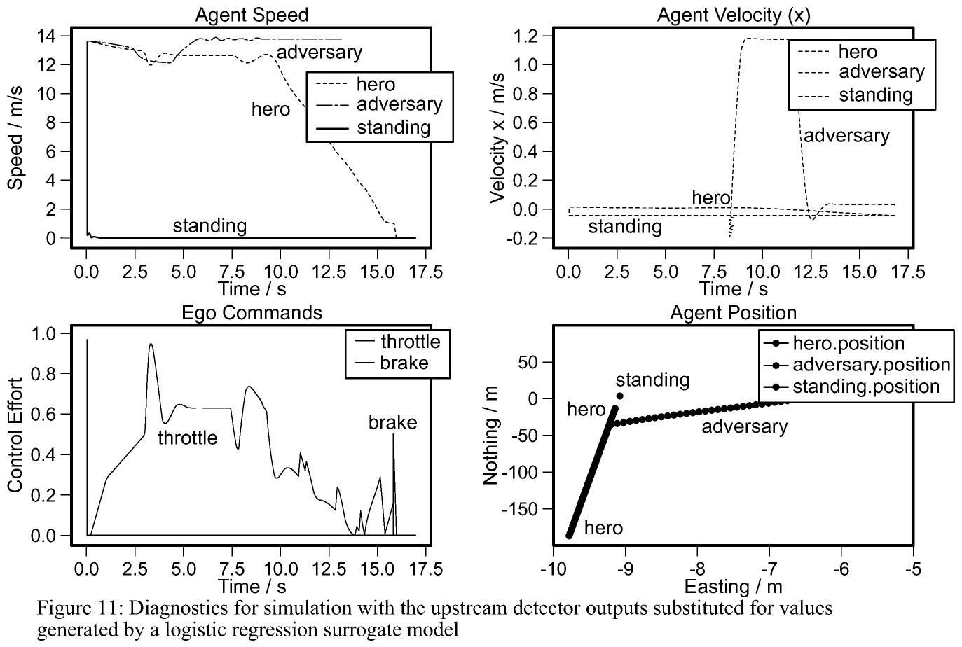

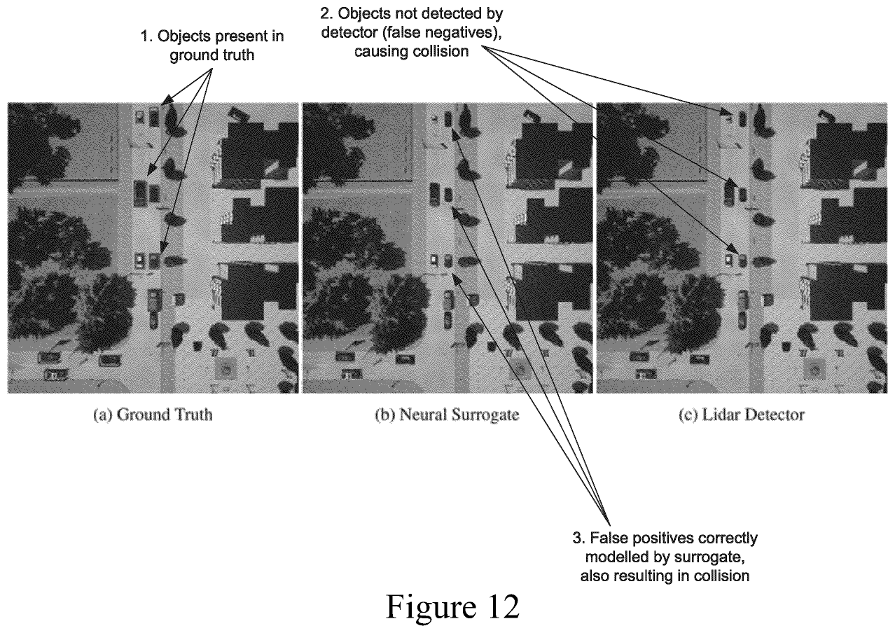

FIG. 12 shows examples of lidar detector errors which cause collisions which are reproduced by the surrogate model, and would not be reproduced if ground truth values were used in place of the backbone model in simulation. The lidar detector has failed to recognize a number of objects present in the ground truth (false negatives), resulting in a collision.

These false positives are correctly modelled by the surrogate, also resulting in collision. The performance of the surrogate relative to the lidar detector is therefore similar on the downstream metrics. Equally, the downstream performance of the lidar detector relative to the ground truth is poor (case no collision occurs when the downstream task is performed on the ground truth) and, importantly, the downstream performance of the surrogate relative to the ground truth is similarly poor.

Suppose the surrogate failed to correctly model a false positive, resulting in the lidar detector missing the object immediately in front of the ego, but the surrogate detecting it. In this case, a collision occurs with the lidar detector, but not the surrogate; the surrogate has therefore failed to replicate the behaviour of the detector. This will result in different downstream performance results, correctly capturing this discrepancy.

Now suppose the surrogate failed to correctly model a false positive, but this has minimal impact on downstream performance. This will result in similar downstream performance results between the surrogate and the detector, correctly capturing the fact that failure to model the false positive correctly had minimal impact on downstream performance.

The above analysis demonstrates that it is possible to create an efficient surrogate corresponding to heavy-compute components (for example, the backbone task of detecting objects) of a complex task such that the input now is much lower-dimensional, and the inference is multiple times faster.

Extensive analysis has been provided to show that such surrogates, while showing similar behaviour to their heavy-compute counterparts when compared using variety of metrics (precision, recall, trajectory similarity, etc.), were multiple times faster as well.

That analysis includes the use of a novel downstream-metric based comparison, to assess the suitability of a surrogate in respect of a given detector or other perception components. The efficacy of this approach has been demonstrated by example in the application to a PIXOR LiDAR detector trained on simulated Carla point clouds, to demonstrate the efficacy of a chosen surrogate model in terms of downstream performance. This is merely one example application, and the same techniques can be extended to assess the suitability of forms of surrogate model in respect of other forms of perception component.

TABLE 5
Carla leaderboard evaluation metrics.

| | LiDAR Det. | | |
|---|---|---|---|
| | (Centerpoint) | NS | GT |
| # Ped. Collisions | 1 | 1 | 1 |
| # Veh. Collisions | 60 | 63 | 23 |
| Avg Completion (%) | 81.870 | 93.933 | 91.373 |
| Median time | 41.250 | 62.800 | 470.950 |
| between collisions | | | |

A testing pipeline to facilitate rules-based testing of mobile robot stacks in real or simulated scenarios will now be described. The described testing pipeline includes capability for surrogate based evaluation and testing, utilizing the methodology set out above.

Agent (actor) behaviour in real or simulated scenarios is evaluated by a test oracle based on defined performance evaluation rules. Such rules may evaluate different facets of safety. For example, a safety rule set may be defined to assess the performance of the stack against a particular safety standard, regulation or safety model (such as RSS), or bespoke rule sets may be defined for testing any aspect of performance. The testing pipeline is not limited in its application to safety, and can be used to test any aspects of performance, such as comfort or progress towards some defined goal. A rule editor allows performance evaluation rules to be defined or modified and passed to the test oracle.

A “full” stack typically involves everything from processing and interpretation of low-level sensor data (perception), feeding into primary higher-level functions such as prediction and planning, as well as control logic to generate suitable control signals to implement planning-level decisions (e.g. to control braking, steering, acceleration etc.). For autonomous vehicles, level 3 stacks include some logic to implement transition demands and level 4 stacks additionally include some logic for implementing minimum risk maneuvers. The stack may also implement secondary control functions e.g. of signalling, headlights, windscreen wipers etc.

The term “stack” can also refer to individual sub-systems (sub-stacks) of the full stack, such as perception, prediction, planning or control stacks, which may be tested individually or in any desired combination. A stack can refer purely to software, i.e. one or more computer programs that can be executed on one or more general-purpose computer processors.

Whether real or simulated, a scenario requires an ego agent to navigate a real or modelled physical context. The ego agent is a real or simulated mobile robot that moves under the control of the stack under testing. The physical context includes static and/or dynamic element(s) that the stack under testing is required to respond to effectively. For example, the mobile robot may be a fully or semi-autonomous vehicle under the control of the stack (the ego vehicle). The physical context may comprise a static road layout and a given set of environmental conditions (e.g. weather, time of day, lighting conditions, humidity, pollution/particulate level etc.) that could be maintained or varied as the scenario progresses. An interactive scenario additionally includes one or more other agents (“external” agent(s), e.g. other vehicles, pedestrians, cyclists, animals etc.).

The examples described herein consider applications to autonomous vehicle testing. However, the principles apply equally to other forms of mobile robot.

Scenarios may be represented or defined at different levels of abstraction. More abstracted scenarios accommodate a greater degree of variation. For example, a “cut-in scenario” or a “lane change scenario” are examples of highly abstracted scenarios, characterized by a maneuver or behaviour of interest, that accommodate many variations (e.g. different agent starting locations and speeds, road layout, environmental conditions etc.). A “scenario run” refers to a concrete occurrence of an agent(s) navigating a physical context, optionally in the presence of one or more other agents. For example, multiple runs of a cut-in or lane change scenario could be performed (in the real-world and/or in a simulator) with different agent parameters (e.g. starting location, speed etc.), different road layouts, different environmental conditions, and/or different stack configurations etc. The terms “run” and “instance” are used interchangeably in this context.

In the following examples, the performance of the stack is assessed, at least in part, by evaluating the behaviour of the ego agent in the test oracle against a given set of performance evaluation rules, over the course of one or more runs. The rules are applied to “ground truth” of the (or each) scenario run which, in general, simply means an appropriate representation of the scenario run (including the behaviour of the ego agent) that is taken as authoritative for the purpose of testing. Ground truth is inherent to simulation; a simulator computes a sequence of scenario states, which is, by definition, a perfect, authoritative representation of the simulated scenario run. In a real-world scenario run, a “perfect” representation of the scenario run does not exist in the same sense; nevertheless, suitably informative ground truth can be obtained in numerous ways, e.g. based on manual annotation of on-board sensor data, automated/semi-automated annotation of such data (e.g. using offline/non-real time processing), and/or using external information sources (such as external sensors, maps etc.) etc.

The scenario ground truth typically includes a “trace” of the ego agent and any other (salient) agent(s) as applicable. A trace is a history of an agent's location and motion over the course of a scenario. There are many ways a trace can be represented. Trace data will typically include spatial and motion data of an agent within the environment. The term is used in relation to both real scenarios (with real-world traces) and simulated scenarios (with simulated traces). The trace typically records an actual trajectory realized by the agent in the scenario. With regards to terminology, a “trace” and a “trajectory” may contain the same or similar types of information (such as a series of spatial and motion states over time). The term trajectory is generally favoured in the context of planning (and can refer to future/predicted trajectories), whereas the term trace is generally favoured in relation to past behaviour in the context of testing/evaluation.

In a simulation context, a “scenario description” is provided to a simulator as input. For example, a scenario description may be encoded using a scenario description language (SDL), or in any other form that can be consumed by a simulator. A scenario description is typically a more abstract representation of a scenario, that can give rise to multiple simulated runs. Depending on the implementation, a scenario description may have one or more configurable parameters that can be varied to increase the degree of possible variation. The degree of abstraction and parameterization is a design choice. For example, a scenario description may encode a fixed layout, with parameterized environmental conditions (such as weather, lighting etc.). Further abstraction is possible, however, e.g. with configurable road parameter(s) (such as road curvature, lane configuration etc.). The input to the simulator comprises the scenario description together with a chosen set of parameter value(s) (as applicable). The latter may be referred to as a parameterization of the scenario. The configurable parameter(s) define a parameter space (also referred to as the scenario space), and the parameterization corresponds to a point in the parameter space. In this context, a “scenario instance” may refer to an instantiation of a scenario in a simulator based on a scenario description and (if applicable) a chosen parameterization.

For conciseness, the term scenario may also be used to refer to a scenario run, as well a scenario in the more abstracted sense. The meaning of the term scenario will be clear from the context in which it is used.

Trajectory planning is an important function in the present context, and the terms “trajectory planner”, “trajectory planning system” and “trajectory planning stack” may be used interchangeably herein to refer to a component or components that can plan trajectories for a mobile robot into the future. Trajectory planning decisions ultimately determine the actual trajectory realized by the ego agent (although, in some testing contexts, this may be influenced by other factors, such as the implementation of those decisions in the control stack, and the real or modelled dynamic response of the ego agent to the resulting control signals).

A trajectory planner may be tested in isolation, or in combination with one or more other systems (e.g. perception, prediction and/or control). Within a full stack, planning generally refers to higher-level autonomous decision-making capability (such as trajectory planning), whilst control generally refers to the lower-level generation of control signals for carrying out those autonomous decisions. However, in the context of performance testing, the term control is also used in the broader sense. For the avoidance of doubt, when a trajectory planner is said to control an ego agent in simulation, that does not necessarily imply that a control system (in the narrower sense) is tested in combination with the trajectory planner.

### Example AV Stack:

To provide relevant context to the described embodiments, further details of an example form of AV stack will now be described.

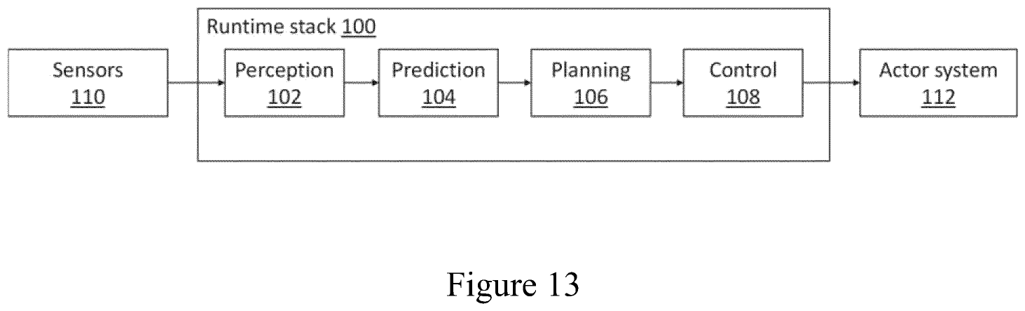

FIG. 13 shows a highly schematic block diagram of an AV runtime stack 100. The run time stack 100 is shown to comprise a perception (sub-)system 102, a prediction (sub-)system 104, a planning (sub-)system (planner) 106 and a control (sub-)system (controller) 108. As noted, the term (sub-)stack may also be used to describe the aforementioned components 102-108.

In a real-world context, the perception system 102 receives sensor outputs from an on-board sensor system 110 of the AV, and uses those sensor outputs to detect external agents and measure their physical state, such as their position, velocity, acceleration etc. The on-board sensor system 110 can take different forms but generally comprises a variety of sensors such as image capture devices (cameras/optical sensors), lidar and/or radar unit(s), satellite-positioning sensor(s) (GPS etc.), motion/inertial sensor(s) (accelerometers, gyroscopes etc.) etc. The onboard sensor system 110 thus provides rich sensor data from which it is possible to extract detailed information about the surrounding environment, and the state of the AV and any external actors (vehicles, pedestrians, cyclists etc.) within that environment. The sensor outputs typically comprise sensor data of multiple sensor modalities such as stereo images from one or more stereo optical sensors, lidar, radar etc. Sensor data of multiple sensor modalities may be combined using filters, fusion components etc.

The perception system 102 typically comprises multiple perception components which co-operate to interpret the sensor outputs and thereby provide perception outputs to the prediction system 104.

In a simulation context, depending on the nature of the testing—and depending, in particular, on where the stack 100 is “sliced” for the purpose of testing (see below)—it may or may not be necessary to model the on-board sensor system 100. With higher-level slicing, simulated sensor data is not required therefore complex sensor modelling is not required.

The perception outputs from the perception system 102 are used by the prediction system 104 to predict future behaviour of external actors (agents), such as other vehicles in the vicinity of the AV.

Predictions computed by the prediction system 104 are provided to the planner 106, which uses the predictions to make autonomous driving decisions to be executed by the AV in a given driving scenario. The inputs received by the planner 106 would typically indicate a drivable area and would also capture predicted movements of any external agents (obstacles, from the AV's perspective) within the drivable area. The driveable area can be determined using perception outputs from the perception system 102 in combination with map information, such as an HD (high definition) map.

A core function of the planner 106 is the planning of trajectories for the AV (ego trajectories), taking into account predicted agent motion. This may be referred to as trajectory planning. A trajectory is planned in order to carry out a desired goal within a scenario. The goal could for example be to enter a roundabout and leave it at a desired exit; to overtake a vehicle in front; or to stay in a current lane at a target speed (lane following). The goal may, for example, be determined by an autonomous route planner (not shown).

The controller 108 executes the decisions taken by the planner 106 by providing suitable control signals to an on-board actor system 112 of the AV. In particular, the planner 106 plans trajectories for the AV and the controller 108 generates control signals to implement the planned trajectories. Typically, the planner 106 will plan into the future, such that a planned trajectory may only be partially implemented at the control level before a new trajectory is planned by the planner 106. The actor system 112 includes “primary” vehicle systems, such as braking, acceleration and steering systems, as well as secondary systems (e.g. signalling, wipers, headlights etc.).

Note, there may be a distinction between a planned trajectory at a given time instant, and the actual trajectory followed by the ego agent. Planning systems typically operate over a sequence of planning steps, updating the planned trajectory at each planning step to account for any changes in the scenario since the previous planning step (or, more precisely, any changes that deviate from the predicted changes). The planning system 106 may reason into the future, such that the planned trajectory at each planning step extends beyond the next planning step. Any individual planned trajectory may, therefore, not be fully realized (if the planning system 106 is tested in isolation, in simulation, the ego agent may simply follow the planned trajectory exactly up to the next planning step; however, as noted, in other real and simulation contexts, the planned trajectory may not be followed exactly up to the next planning step, as the behaviour of the ego agent could be influenced by other factors, such as the operation of the control system 108 and the real or modelled dynamics of the ego vehicle). In many testing contexts, the actual trajectory of the ego agent is what ultimately matters; in particular, whether the actual trajectory is safe, as well as other factors such as comfort and progress. However, the rules-based testing approach herein can also be applied to planned trajectories (even if those planned trajectories are not fully or exactly realized by the ego agent). For example, even if the actual trajectory of an agent is deemed safe according to a given set of safety rules, it might be that an instantaneous planned trajectory was unsafe; the fact that the planner 106 was considering an unsafe course of action may be revealing, even if it did not lead to unsafe agent behaviour in the scenario. Instantaneous planned trajectories constitute one form of internal state that can be usefully evaluated, in addition to actual agent behaviour in the simulation. Other forms of internal stack state can be similarly evaluated.

The example of FIG. 13 considers a relatively “modular” architecture, with separable perception, prediction, planning and control systems 102-108. The sub-stack themselves may also be modular, e.g. with separable planning modules within the planning system 106. For example, the planning system 106 may comprise multiple trajectory planning modules that can be applied in different physical contexts (e.g. simple lane driving vs. complex junctions or roundabouts). This is relevant to simulation testing for the reasons noted above, as it allows components (such as the planning system 106 or individual planning modules thereof) to be tested individually or in different combinations. For the avoidance of doubt, with modular stack architectures, the term stack can refer not only to the full stack but to any individual sub-system or module thereof.

The extent to which the various stack functions are integrated or separable can vary significantly between different stack implementations—in some stacks, certain aspects may be so tightly coupled as to be indistinguishable. For example, in other stacks, planning and control may be integrated (e.g. such stacks could plan in terms of control signals directly), whereas other stacks (such as that depicted in FIG. 13) may be architected in a way that draws a clear distinction between the two (e.g. with planning in terms of trajectories, and with separate control optimizations to determine how best to execute a planned trajectory at the control signal level). Similarly, in some stacks, prediction and planning may be more tightly coupled. At the extreme, in so-called “end-to-end” driving, perception, prediction, planning and control may be essentially inseparable. Unless otherwise indicated, the perception, prediction planning and control terminology used herein does not imply any particular coupling or modularity of those aspects.

It will be appreciated that the term “stack” encompasses software, but can also encompass hardware. In simulation, software of the stack may be tested on a “generic” off-board computer system, before it is eventually uploaded to an on-board computer system of a physical vehicle. However, in “hardware-in-the-loop” testing, the testing may extend to underlying hardware of the vehicle itself. For example, the stack software may be run on the on-board computer system (or a replica thereof) that is coupled to the simulator for the purpose of testing. In this context, the stack under testing extends to the underlying computer hardware of the vehicle. As another example, certain functions of the stack 110 (e.g. perception functions) may be implemented in dedicated hardware. In a simulation context, hardware-in-the loop testing could involve feeding synthetic sensor data to dedicated hardware perception components.

### Example Testing Paradigm:

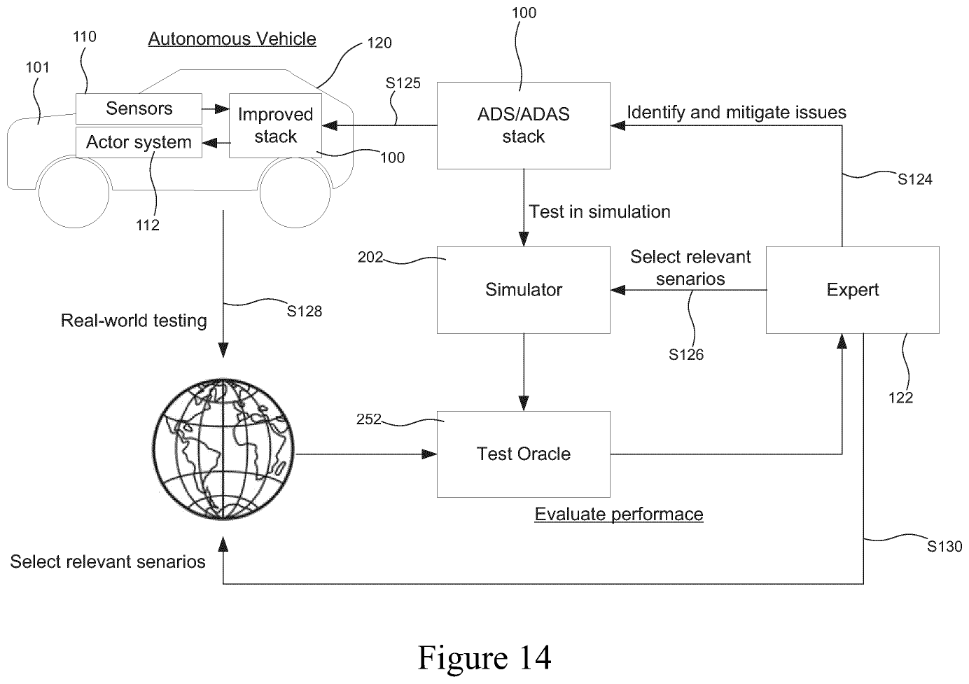

FIG. 14 shows a highly schematic overview of a testing paradigm for autonomous vehicles. An ADS/ADAS stack 100, e.g. of the kind depicted in FIG. 13, is subject to repeated testing and evaluation in simulation, by running multiple scenario instances in a simulator 202, and evaluating the performance of the stack 100 (and/or individual subs-stacks thereof) in a test oracle 252. The output of the test oracle 252 is informative to an expert 122 (team or individual), allowing them to identify issues in the stack 100 and modify the stack 100 to mitigate those issues (S124). The results also assist the expert 122 in selecting further scenarios for testing (S126), and the process continues, repeatedly modifying, testing and evaluating the performance of the stack 100 in simulation. The improved stack 100 is eventually incorporated (S125) in a real-world AV 101, equipped with a sensor system 110 and an actor system 112. The improved stack 100 typically includes program instructions (software) executed in one or more computer processors of an on-board computer system of the vehicle 101 (not shown). The software of the improved stack is uploaded to the AV 101 at step S125. Step S125 may also involve modifications to the underlying vehicle hardware. On board the AV 101, the improved stack 100 receives sensor data from the sensor system 110 and outputs control signals to the actor system 112. Real-world testing (S128) can be used in combination with simulation-based testing. For example, having reached an acceptable level of performance though the process of simulation testing and stack refinement, appropriate real-world scenarios may be selected (S130), and the performance of the AV 101 in those real scenarios may be captured and similarly evaluated in the test oracle 252.

Scenarios can be obtained for the purpose of simulation in various ways, including manual encoding. The system is also capable of extracting scenarios for the purpose of simulation from real-world runs, allowing real-world situations and variations thereof to be re-created in the simulator 202.

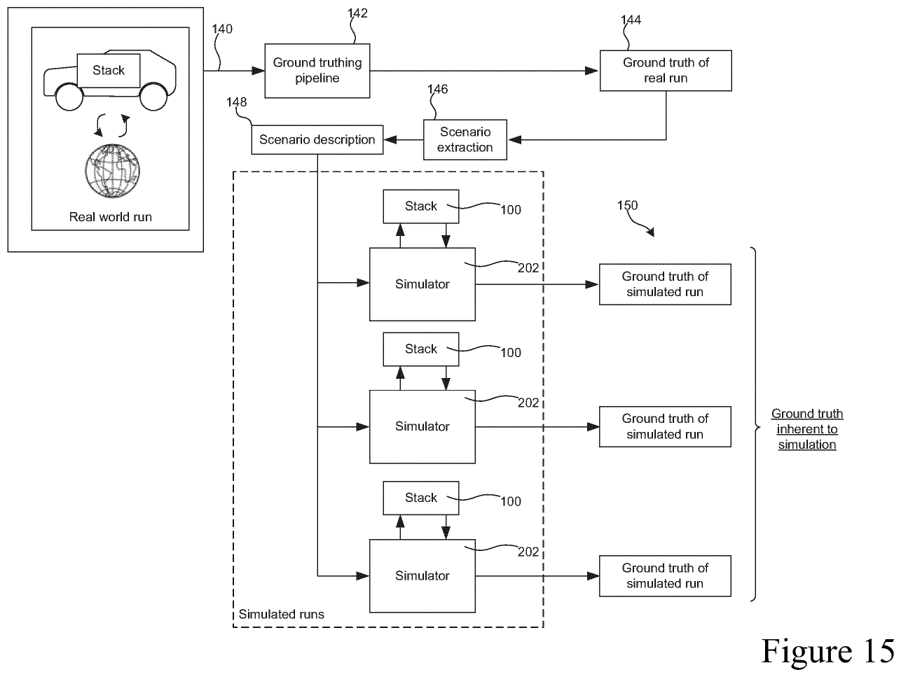

FIG. 15 shows a highly schematic block diagram of a scenario extraction pipeline. Data 140 of a real-world run is passed to a ‘ground-truthing’ pipeline 142 for the purpose of generating scenario ground truth. The run data 140 could comprise, for example, sensor data and/or perception outputs captured/generated on board one or more vehicles (which could be autonomous, human-driven or a combination thereof), and/or data captured from other sources such external sensors (CCTV etc.). The run data is processed within the ground truthing pipeline 142, in order to generate appropriate ground truth 144 (trace(s) and contextual data) for the real-world run. As discussed, the ground-truthing process could be based on manual annotation of the ‘raw’ run data 140, or the process could be entirely automated (e.g. using offline perception method(s)), or a combination of manual and automated ground truthing could be used. For example, 3D bounding boxes may be placed around vehicles and/or other agents captured in the run data 140, in order to determine spatial and motion states of their traces. A scenario extraction component 146 receives the scenario ground truth 144, and processes the scenario ground truth 144 to extract a more abstracted scenario description 148 that can be used for the purpose of simulation. The scenario description 148 is consumed by the simulator 202, allowing multiple simulated runs to be performed. The simulated runs are variations of the original real-world run, with the degree of possible variation determined by the extent of abstraction. Ground truth 150 is provided for each simulated run.

In the present off-board content, there is no requirement for the traces to be extracted in real-time (or, more precisely, no need for them to be extracted in a manner that would support real-time planning); rather, the traces are extracted “offline”. Examples of offline perception algorithms include non-real time and non-causal perception algorithms. Offline techniques contrast with “on-line” techniques that can feasibly be implemented within an AV stack 100 to facilitate real-time planning/decision making.

For example, it is possible to use non-real time processing, which cannot be performed on-line due to hardware or other practical constraints of an AV's onboard computer system. For example, one or more non-real time perception algorithms can be applied to the real-world run data 140 to extract the traces. A non-real time perception algorithm could be an algorithm that it would not be feasible to run in real time because of the computation or memory resources it requires.

It is also possible to use “non-causal” perception algorithms in this context. A non-causal algorithm may or may not be capable of running in real-time at the point of execution, but in any event could not be implemented in an online context, because it requires knowledge of the future. For example, a perception algorithm that detects an agent state (e.g. location, pose, speed etc.) at a particular time instant based on subsequent data could not support real-time planning within the stack 100 in an on-line context, because it requires knowledge of the future (unless it was constrained to operate with a short look ahead window). For example, filtering with a backwards pass is a non-causal algorithm that can sometimes be run in real-time, but requires knowledge of the future.

The term “perception” generally refers to techniques for perceiving structure in the real-world data 140, such as 2D or 3D bounding box detection, location detection, pose detection, motion detection etc. For example, a trace may be extracted as a time-series of bounding boxes or other spatial states in 3D space or 2D space (e.g. in a birds-eye-view frame of reference), with associated motion information (e.g. speed, acceleration, jerk etc.). In the context of image processing, such techniques are often classed as “computer vision”, but the term perception encompasses a broader range of sensor modalities.

### Testing Pipeline:

Further details of the testing pipeline and the test oracle 252 will now be described. The examples that follow focus on simulation-based testing. However, as noted, the test oracle 252 can equally be applied to evaluate stack performance on real scenarios, and the relevant description below applies equally to real scenarios. The following description refers to the stack 100 of FIG. 13 by way of example. However, as noted, the testing pipeline 200 is highly flexible and can be applied to any stack or sub-stack operating at any level of autonomy.

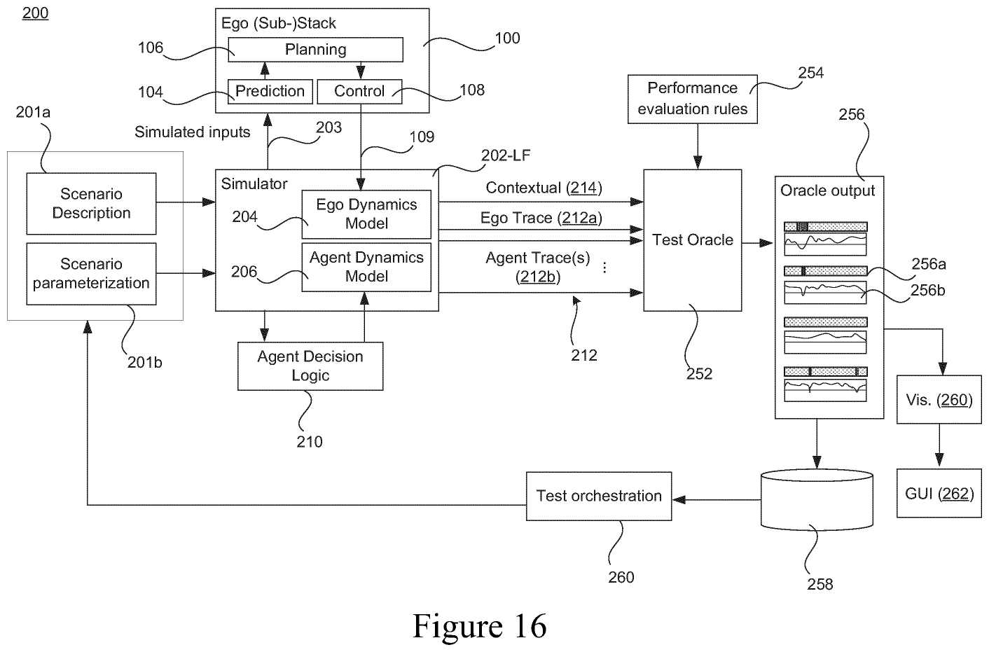

FIG. 16 shows a schematic block diagram of the testing pipeline, denoted by reference numeral 200. The testing pipeline 200 is shown to comprise the simulator 202 and the test oracle 252. The simulator 202 runs simulated scenarios for the purpose of testing all or part of an AV run time stack 100, and the test oracle 252 evaluates the performance of the stack (or sub-stack) on the simulated scenarios. As discussed, it may be that only a sub-stack of the run-time stack is tested, but for simplicity, the following description refers to the (full) AV stack 100 throughout. However, the description applies equally to a sub-stack in place of the full stack 100. The term “slicing” is used herein to the selection of a set or subset of stack components for testing.

As described previously, the idea of simulation-based testing is to run a simulated driving scenario that an ego agent must navigate under the control of the stack 100 being tested. Typically, the scenario includes a static drivable area (e.g. a particular static road layout) that the ego agent is required to navigate, typically in the presence of one or more other dynamic agents (such as other vehicles, bicycles, pedestrians etc.). To this end, simulated inputs 203 are provided from the simulator 202 to the stack 100 under testing.

The slicing of the stack dictates the form of the simulated inputs 203. By way of example, FIG. 16 shows the prediction, planning and control systems 104, 106 and 108 within the AV stack 100 being tested. To test the full AV stack of FIG. 13, the perception system 102 could also be applied during testing. In this case, the simulated inputs 203 would comprise synthetic sensor data that is generated using appropriate sensor model(s) and processed within the perception system 102 in the same way as real sensor data. This requires the generation of sufficiently realistic synthetic sensor inputs (such as photorealistic image data and/or equally realistic simulated lidar/radar data etc.). The resulting outputs of the perception system 102 would, in turn, feed into the higher-level prediction and planning systems 104, 106.

By contrast, so-called “planning-level” simulation would essentially bypass the perception system 102. The simulator 202 would instead provide simpler, higher-level inputs 203 directly to the prediction system 104. In some contexts, it may even be appropriate to bypass the prediction system 104 as well, in order to test the planner 106 on predictions obtained directly from the simulated scenario (i.e. “perfect” predictions).

Between these extremes, there is scope for many different levels of input slicing, e.g. testing only a subset of the perception system 102, such as “later” (higher-level) perception components, e.g. components such as filters or fusion components which operate on the outputs from lower-level perception components (such as object detectors, bounding box detectors, motion detectors etc.).

Whatever form they take, the simulated inputs 203 are used (directly or indirectly) as a basis for decision-making by the planner 108. The controller 108, in turn, implements the planner's decisions by outputting control signals 109. In a real-world context, these control signals would drive the physical actor system 112 of AV. In simulation, an ego vehicle dynamics model 204 is used to translate the resulting control signals 109 into realistic motion of the ego agent within the simulation, thereby simulating the physical response of an autonomous vehicle to the control signals 109.

Alternatively, a simpler form of simulation assumes that the ego agent follows each planned trajectory exactly between planning steps. This approach bypasses the control system 108 (to the extent it is separable from planning) and removes the need for the ego vehicle dynamic model 204. This may be sufficient for testing certain facets of planning.

To the extent that external agents exhibit autonomous behaviour/decision making within the simulator 202, some form of agent decision logic 210 is implemented to carry out those decisions and determine agent behaviour within the scenario. The agent decision logic 210 may be comparable in complexity to the ego stack 100 itself or it may have a more limited decision-making capability. The aim is to provide sufficiently realistic external agent behaviour within the simulator 202 to be able to usefully test the decision-making capabilities of the ego stack 100. In some contexts, this does not require any agent decision making logic 210 at all (open-loop simulation), and in other contexts useful testing can be provided using relatively limited agent logic 210 such as basic adaptive cruise control (ACC). One or more agent dynamics models 206 may be used to provide more realistic agent behaviour if appropriate.

A scenario is run in accordance with a scenario description 201a and (if applicable) a chosen parameterization 201b of the scenario. A scenario typically has both static and dynamic elements which may be “hard coded” in the scenario description 201a or configurable and thus determined by the scenario description 201a in combination with a chosen parameterization 201b. In a driving scenario, the static element(s) typically include a static road layout.

The dynamic element(s) typically include one or more external agents within the scenario, such as other vehicles, pedestrians, bicycles etc.

The extent of the dynamic information provided to the simulator 202 for each external agent can vary. For example, a scenario may be described by separable static and dynamic layers. A given static layer (e.g. defining a road layout) can be used in combination with different dynamic layers to provide different scenario instances. The dynamic layer may comprise, for each external agent, a spatial path to be followed by the agent together with one or both of motion data and behaviour data associated with the path. In simple open-loop simulation, an external actor simply follows the spatial path and motion data defined in the dynamic layer that is non-reactive i.e. does not react to the ego agent within the simulation. Such open-loop simulation can be implemented without any agent decision logic 210. However, in closed-loop simulation, the dynamic layer instead defines at least one behaviour to be followed along a static path (such as an ACC behaviour). In this case, the agent decision logic 210 implements that behaviour within the simulation in a reactive manner, i.e. reactive to the ego agent and/or other external agent(s). Motion data may still be associated with the static path but in this case is less prescriptive and may for example serve as a target along the path. For example, with an ACC behaviour, target speeds may be set along the path which the agent will seek to match, but the agent decision logic 210 might be permitted to reduce the speed of the external agent below the target at any point along the path in order to maintain a target headway from a forward vehicle.

As will be appreciated, scenarios can be described for the purpose of simulation in many ways, with any degree of configurability. For example, the number and type of agents, and their motion information may be configurable as part of the scenario parameterization 201b.

The output of the simulator 202 for a given simulation includes an ego trace 212a of the ego agent and one or more agent traces 212b of the one or more external agents (traces 212). Each trace 212a, 212b is a complete history of an agent's behaviour within a simulation having both spatial and motion components. For example, each trace 212a, 212b may take the form of a spatial path having motion data associated with points along the path such as speed, acceleration, jerk (rate of change of acceleration), snap (rate of change of jerk) etc.

Additional information is also provided to supplement and provide context to the traces 212. Such additional information is referred to as “contextual” data 214. The contextual data 214 pertains to the physical context of the scenario, and can have both static components (such as road layout) and dynamic components (such as weather conditions to the extent they vary over the course of the simulation). To an extent, the contextual data 214 may be “passthrough” in that it is directly defined by the scenario description 201a or the choice of parameterization 201b, and is thus unaffected by the outcome of the simulation. For example, the contextual data 214 may include a static road layout that comes from the scenario description 201a or the parameterization 201b directly. However, typically the contextual data 214 would include at least some elements derived within the simulator 202. This could, for example, include simulated environmental data, such as weather data, where the simulator 202 is free to change weather conditions as the simulation progresses. In that case, the weather data may be time-dependent, and that time dependency will be reflected in the contextual data 214.

The test oracle 252 receives the traces 212 and the contextual data 214, and scores those outputs in respect of a set of performance evaluation rules 254. The performance evaluation rules 254 are shown to be provided as an input to the test oracle 252.

The rules 254 are categorical in nature (e.g. pass/fail-type rules). Certain performance evaluation rules are also associated with numerical performance metrics used to “score” trajectories (e.g. indicating a degree of success or failure or some other quantity that helps explain or is otherwise relevant to the categorical results). The evaluation of the rules 254 is time-based—a given rule may have a different outcome at different points in the scenario. The scoring is also time-based: for each performance evaluation metric, the test oracle 252 tracks how the value of that metric (the score) changes over time as the simulation progresses. The test oracle 252 provides an output 256 (performance testing results) comprising a time sequence 256a of categorical (e.g. pass/fail) results for each rule, and a score-time plot 256b for each performance metric, as described in further detail later. The results and scores 256a, 256b are informative to the expert 122 and can be used to identify and mitigate performance issues within the tested stack 100. The test oracle 252 also provides an overall (aggregate) result for the scenario (e.g. overall pass/fail). The output 256 of the test oracle 252 is stored in a test database 258, in association with information about the scenario to which the output 256 pertains. For example, the output 256 may be stored in association with the scenario description 210a (or an identifier thereof), and the chosen parameterization 201b. As well as the time-dependent results and scores, an overall score may also be assigned to the scenario and stored as part of the output 256. For example, an aggregate score for each rule (e.g. overall pass/fail) and/or an aggregate result (e.g. pass/fail) across all of the rules 254.

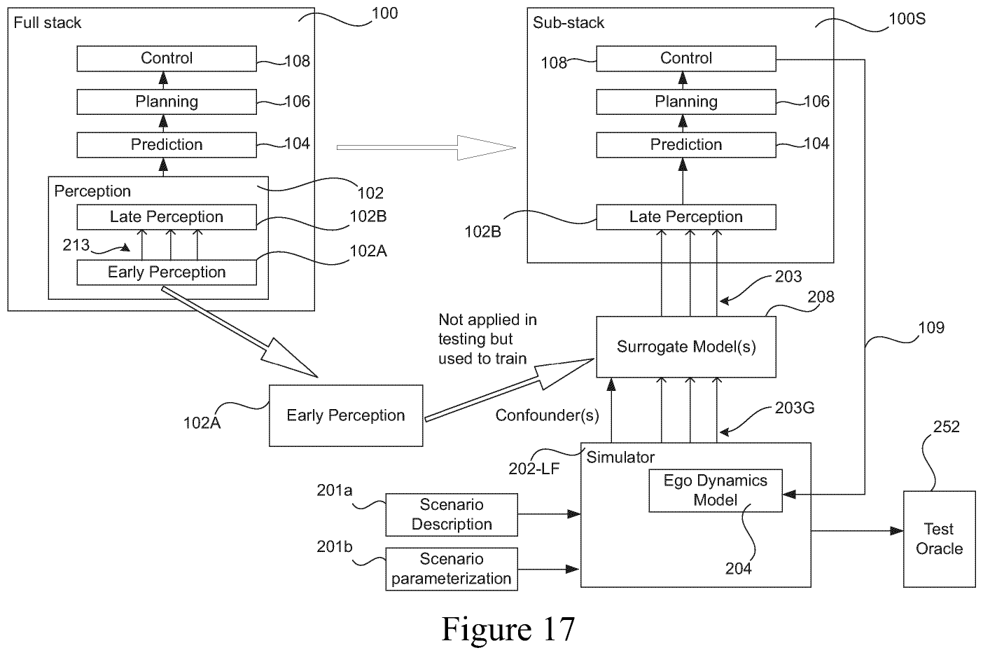

FIG. 17 illustrates another choice of slicing and uses reference numerals 100 and 100S to denote a full stack and sub-stack respectively. It is the sub-stack 100S that would be subject to testing within the testing pipeline 200 of FIG. 16.

A number of “later” perception components 102B form part of the sub-stack 100S to be tested and are applied, during testing, to simulated perception inputs 203. The later perception components 102B could, for example, include filtering or other fusion components that fuse perception inputs from multiple earlier perception components.

In the full stack 100, the later perception components 102B would receive actual perception inputs 213 from earlier perception components 102A. For example, the earlier perception components 102A might comprise one or more 2D or 3D bounding box detectors, in which case the simulated perception inputs provided to the late perception components could include simulated 2D or 3D bounding box detections, derived in the simulation via ray tracing. The earlier perception components 102A would generally include component(s) that operate directly on sensor data. With the slicing of FIG. 13, the simulated perception inputs 203 would correspond in form to the actual perception inputs 213 that would normally be provided by the earlier perception components 102A. However, the earlier perception components 102A are not applied as part of the testing, but are instead used to train one or more perception error models 208 that can be used to introduce realistic error, in a statistically rigorous manner, into the simulated perception inputs 203 that are fed to the later perception components 102B of the sub-stack 100 under testing. The perception error model(s) 208 serves as a surrogate model (\tilde{ƒ}) in the sense described above (being a surrogate for the perception system 102, or part of the perception system 102A, but operating on lower-fidelity inputs).

Such perception error models may be referred to as Perception Statistical Performance Models (PSPMs) or, synonymously, “PRISMs”. Further details of the principles of PSPMs, and suitable techniques for building and training them, may be bound in International Patent Publication Nos. WO2021037763 WO2021037760, WO2021037765, WO2021037761, and WO2021037766, each of which is incorporated herein by reference in its entirety. The idea behind PSPMs is to efficiently introduce realistic errors into the simulated perception inputs provided to the sub-stack 100S (i.e. that reflect the kind of errors that would be expected were the earlier perception components 102A to be applied in the real-world). In a simulation context, “perfect” ground truth perception inputs 203G are provided by the simulator, but these are used to derive more realistic (ablated) perception inputs 203 with realistic error introduced by the perception error models(s) 208.

As described in the aforementioned reference, a PSPM can be dependent on one or more variables representing physical condition(s) (“confounders”), allowing different levels of error to be introduced that reflect different possible real-world conditions. Hence, the simulator 202 can simulate different physical conditions (e.g. different weather conditions) by simply changing the value of a weather confounder(s), which will, in turn, change how perception error is introduced.

The later perception components 102b within the sub-stack 100S process the simulated perception inputs 203 in exactly the same way as they would process the real-world perception inputs 213 within the full stack 100, and their outputs, in turn, drive prediction, planning and control.

Alternatively, PRISMs can be used to model the entire perception system 102, including the late perception components 208, in which case a PSPM(s) is used to generate realistic perception output that are passed as inputs to the prediction system 104 directly.

Depending on the implementation, there may or may not be deterministic relationship between a given scenario parameterization 201b and the outcome of the simulation for a given configuration of the stack 100 (i.e. the same parameterization may or may not always lead to the same outcome for the same stack 100). Non-determinism can arise in various ways. For example, when simulation is based on PRISMs, a PRISM might model a distribution over possible perception outputs at each given time step of the scenario, from which a realistic perception output is sampled probabilistically. This leads to non-deterministic behaviour within the simulator 202, whereby different outcomes may be obtained for the same stack 100 and scenario parameterization because different perception outputs are sampled. Alternatively, or additionally, the simulator 202 may be inherently non-deterministic, e.g. weather, lighting or other environmental conditions may be randomized/probabilistic within the simulator 202 to a degree. As will be appreciated, this is a design choice: in other implementations, varying environmental conditions could instead be fully specified in the parameterization 201b of the scenario. With non-deterministic simulation, multiple scenario instances could be run for each parameterization. An aggregate pass/fail result could be assigned to a particular choice of parameterization 201b, e.g. as a count or percentage of pass or failure outcomes.

A test orchestration component 260 is responsible for selecting scenarios for the purpose of simulation. For example, the test orchestration component 260 may select scenario descriptions 201a and suitable parameterizations 201b automatically, which may be based on the test oracle outputs 256 from previous scenarios and/or other criteria.

A visualization component 260 has the capability to render the performance testing results 256 on a graphical user interface (GUI) 262.

In addition to the rules-based testing, the test oracle 252 implements the above downstream metrics, to enable a comparison between downstream performance on low-fidelity simulations and high-fidelity scenarios (real or simulated). Such performance can be assessed using e.g. some external reference planner (e.g. ACC) or prediction system, or the planner/prediction system(s) 104, 106 within the stack 100 itself.

To assess the suitability of the surrogate model(s) 208, certain scenarios may be simulated in both low-fidelity (without the surrogate) and in low fidelity (with the surrogate). The above downstream metric-based comparisons may be used to evaluate the results (though direct and/or indirect comparison), and the GUI 262 is in turn populated with those results. Once the suitability of the surrogate 208 has been demonstrated on a sufficient range of scenarios, it can be used with confidence thereafter in further performance testing (based only on low-fidelity simulations).

Alternatively, ego performance in a selection of real-world scenarios may be evaluated in the test oracle. Those scenarios can then be re-produced in low-fidelity simulation, e.g. via the pipeline of FIG. 15, allowing the downstream performance metric or metrics to be evaluated between the real scenarios and their low fidelity counterparts. Indirect comparison can be effected using the ground truth 144 extracted in FIG. 15 (or, alternatively, ground truth obtained through manual annotation). The GUI 262 can then be populated with the results, to enable the user to assess the suitability of the surrogate 208.

Although the described embodiments consider upstream perception components/systems, and specifically object detectors, assessed in relation to downstream planning components/systems, the techniques can be applied more generally to other forms of component. For example, an upstream processing component could be a prediction system and a downstream processing system could be a planning system. In such cases, prediction performance is assessed in terms of downstream planner performance. As another example, the upstream processing component could be a perception system and the downstream processing component could be a prediction system. In such cases, perception performance is assessed in terms of prediction performance.

The above examples consider an AV testing context, where a substitute upstream processing component takes the form of a surrogate model operating on lower-fidelity inputs. However, the present techniques can be applied in other contexts. For example, it may be desirable to modify an existing AV stack, by replacing an upstream component with a new component that is faster or more efficient (in terms of processing and/or memory resources), but without materially altering downstream performance. In this case, the substitute upstream processing component may operate on the same form of inputs (e.g. high-fidelity sensor inputs) as the existing upstream processing component.

One example might be an existing component that supports good downstream performance, but does not have a fixed execution time is not able to consistently operate in real-time. In this case, it may be desirable to replace the existing upstream component (e.g. perception or prediction system) with, e.g., a convolutional or other neural network trained to approximate the existing upstream component, but with a fixed execution time, thus guaranteeing real-time operation. In this context, the downstream-metric-based techniques described herein may be used to assess performance of the neural network is assessed in training in terms of downstream performance (e.g. resulting prediction or planning performance); that is, in terms of whether similar downstream performance is achieved with the new downstream component (e.g. similar prediction or planning performance).

References herein to components, functions, modules and the like, denote functional components of a computer system which may be implemented at the hardware level in various ways. A computer system comprises execution hardware which may be configured to execute the method/algorithmic steps disclosed herein and/or to implement a model trained using the present techniques. The term execution hardware encompasses any form/combination of hardware configured to execute the relevant method/algorithmic steps. The execution hardware may take the form of one or more processors, which may be programmable or non-programmable, or a combination of programmable and non-programmable hardware may be used. Examples of suitable programmable processors include general purpose processors based on an instruction set architecture, such as CPUs, GPUs/accelerator processors etc. Such general-purpose processors typically execute computer readable instructions held in memory coupled to or internal to the processor and carry out the relevant steps in accordance with those instructions. Other forms of programmable processors include field programmable gate arrays (FPGAs) having a circuit configuration programmable through circuit description code. Examples of non-programmable processors include application specific integrated circuits (ASICs). Code, instructions etc. may be stored as appropriate on transitory or non-transitory media (examples of the latter including solid state, magnetic and optical storage device(s) and the like).

### REFERENCES

Each of the following is incorporated herein by reference
[1] Afsoon Afzal, Deborah S Katz, Claire Le Goues, and Christopher S Timperley. A study on the challenges of using robotics simulators for testing. arXiv preprint arXiv: 2004.07368, 2020. 1
[2] Henrik Arnelid, Edvin Listo Zec, and Nasser Mohammadiha. Recurrent conditional generative adversarial networks for autonomous driving sensor modelling. In 2019 IEEE Intelligent Transportation Systems Conference (ITSC), pages 1613-1618. IEEE, 2019. 4
[3] Aravind Balakrishnan. Closing the modelling gap: Transfer learning from a low-fidelity simulator for autonomous driving. Master's thesis, University of Waterloo, 2020. 3
[4] Volker Berkhahn. Marcel Kleiber, Johannes Langner. Chris Timmermann, and Stefan Weber. Traffic dynamics at intersections subject to random misperception. 4
[5] NTS Board. Collision between vehicle controlled by developmental automated driving system and pedestrian. Nat. Transpot. Saf. Board, Washington, DC. USA. Tech. Rep. HAR-19-03, 2019. 1
[6] Alexey Dosovitskiy, German Ros, Felipe Codevilla. Antonio Lopez. and Vladlen Koltun. CARLA: An open urban driving simulator. In Proceedings of the 1st Annual Conference on Robot Learning, pages 1-16, 2017. 1, 2, 4
[7] Ahmad El Sallab, Ibrahim Sobh, Mohamed Zahran, and Nader Essam. Lidar sensor modeling and data augmentation with gans for autonomous driving. arXiv, pages arXiv-1905, 2019. 3
[8] Kevin Eykholt, Ivan Evtimov, Earlence Fernandes, Bo Li. Amir Rahmati, Chaowei Xiao, Atul Prakash, Tadayoshi Kohno, and Dawn Song. Robust physical-world attacks on deep learning visual classification. In Proceedings of the IEEE conference on computer vision and pattern recognition, pages 1625-1634, 2018. 1
[9] David A Forsyth and Jean Ponce. Computer vision: a modern approach. Pearson., 2012. 3
[10] Kaiming He, Xiangyu Zhang, Shaoqing Ren, and Jian Sun. Deep residual learning for image recognition. In Proceedings of the IEEE conference on computer vision and pattern recognition, pages 770-778, 2016, 3. 11
[11] Nils Hirsenkorn, Timo Hanke, Andreas Rauch, Bernhard Dehlink, Ralph Rasshofer, and Erwin Biebl. Virtual sensor models for real-time applications. Advances in Radio Science, 14:31-37, 2016, 4
[12] Andrew Illyas, Shibani Santurkar, Dimitris Tsipras, Logan Engstrom, Brandon Tran, and Aleksander Madry, Adversarial examples are not bugs, they are features. In Proceedings of the 33rd International Conference on Neural Information Processing Systems, pages 125-136, 2019. 1
[13] Joel Janai, Fatma Güney, Aseem Behl, Andreas Geiger, et al. Computer vision for autonomous vehicles: Problems, datasets and state of the art. Foundations and Trends® in Computer Graphics and Vision, 12 (1-3): 1-308, 2020. 1
[14] Matthew Johnson-Roberson, Charles Barto, Rounak Mehta, Sharath Nittur Sridhar, Karl Rosaen, and Ram Vasudevan. Driving in the matrix: Can virtual worlds replace human-generated annotations for real world tasks? In 2017 IEEE International Conference on Robotics and Automation (ICRA), pages 746-753. IEEE. 2017. 1
[15] Abhishek Kadian, Joanne Truong, Aaron Gokaslan, Alexander Clegg, Erik Wijmans, Stefan Lee, Manolis Savva, Sonia Chernova, and Dhruv Batra. Are we making real progress in simulated environments? measuring the sim2real gap in embodied visual navigation. arXiv preprint arXiv: 1912.06321, 2019. 3
[16] Alex Kendall and Yarin Gal. What uncertainties do we need in bayesian deep learning for computer vision? In Advances in neural information processing systems, pages 5574-5584, 2017. 3
[17] Alex Kendall, Yarin Gal, and Roberto Cipolla. Multi-task learning using uncertainty to weigh losses for scene geometry and semantics. In Proceedings of the IEEE conference on computer vision and pattern recognition, pages 7482-7491, 2018. 3
[18] Robert Krajewski, Michael Hoss, Adrian Meister, Fabian Thomsen, Julian Bock, and Lutz Eckstein. Neural-networks-based modeling of automotive perception errors using drones as reference sensors. 3,4
[19] Tsung-Yi Lin, Priya Goyal, Ross Girshick, Kaiming He, and Piotr Dollár. Focal loss for dense object detection. In Proceedings of the IEEE international conference on computer vision, pages 2980-2988, 2017. 4
[20] Aleksander Madry, Aleksandar Makelov, Ludwig Schmidt, Dimitris Tsipras, and Adrian Vladu. Towards deep learning models resistant to adversarial attacks. In International Conference on Learning Representations, 2018. 1
[21] Pallavi Mitra, Apratim Choudhury, Vimal Rau Aparow, Giridharan Kulandaivelu, and Justin Dauwels. Towards modeling of perception errors in autonomous vehicles. In 2018 21st International Conference on Intelligent Transportation Systems (ITSC), pages 3024-3029, IEEE, 2018 4
[22] Jishnu Mukhoti, Viveka Kulharia, Amartya Sanyal, Stuart Golodetz, Philip Torr, and Puneet Dokania. Calibrating deep neural networks using focal loss, In H. Larochelle, M Ranzato, R. Hadsell, M. F. Balcan, and H. Lin, editors, Advances in Neural Information Processing Systems, volume 33, pages 15288-15299, Curran Associates, Inc., 2020 4
[23] Ouster, Inc. OSI Mid-Range High Resolution Imaging Lidar, 12
[24] Yaniv Ovadia, Emily Fertig, Jie Ren, Zachary Nado, D Sculley, Sebastian Nowozin, Joshua Dillon, Balaji Lakshmi-narayanan, and Jasper Snoek. Can you trust your model's uncertainty? evaluating predictive uncertainty under dataset shift. Advances in Neural Information Processing Systems, 32:13991-14002, 2019. 1
[25] Jonah Philion, Amlan Kar, and Sanja Fidler. Learning to evaluate perception models using planner-centric metrics. In Proceedings of the IEEE/CVF Conference on Computer Vision and Pattern Recognition, pages 14055-14064, 2020. 4, 5,13
[26] Andrea Piazzoni, Jim Cherian, Martin Slavik, and Justin Dauwels. Modeling perception errors towards robust decision making in autonomous vehicles. In IJCAI, 2020. 4
[27] Andrea Piazzoni, Jim Cherian, Martin Slavik, and Justin Dauwels. Modeling sensing and perception errors towards robust decision making in autonomous vehicles. arXiv preprint arXiv: 2001.11695, 2020. 4
[28] Samira Pouyanfar, Muneeb Saleem, Nikhil George, and Shu-Ching Chen. Roads: Randomization for obstacle avoidance and driving in simulation. In Proceedings of the IEEE Conference on Computer Vision and Pattern Recognition Workshops, pages 0-0, 2019. 2, 3
[29] German Ros, Vladfen Koltun, Felipe Codevilla, and Antonio Lopez. The CARLA Autonomous Driving Challenge. https://carlachallenge.org/, 2019. 4
[30] Alexander Suhre and Waqas Malik. Simulating object lists using neural networks in automotive radar. In 2018 19th International Conference on Thermal, Mechanical and Multi-Physics Simulation and Experiments in Microelectronics and Microsystems (EuroSimE), pages 1-5. IEEE, 2018. 4
[31] Ardi Tampuu, Tambet Matiisen, Maksym Semikin, Dmytro Fishman, and Naveed Muhammad. A survey of end-to-end driving: Architectures and training methods. IEEE Transactions on Neural Networks and Learning Systems, 2020. 1
[32] Mingxing Tan, Ruoming Pang, and Quoc V Le. Efficientdet: Scalable and efficient object detection. In Proceedings of the IEEE/CVF conference on computer vision and pattern recognition, pages 10781-10790, 2020. 1
[33] Dimitris Tsipras, Shibani Santurkar, Logan Engstrom, Alexander Turner, and Aleksander Madry. Robustness may be at odds with accuracy. In International Conference on Learning Representations, number 2019, 2019. 1
[34] Jingkang Wang, Ava Pun, James Tu, Sivabalan Manivasagam, Abbas Sadat, Sergio Casas, Mengye Ren, and Raquel Urtasun. Advsim: Generating safety-critical scenarios for self-driving vehicles. CoRR, abs/2101.06549, 2021. 3
[35] Yu Xiang and Silvio Savarese. Object detection by 3d aspectlets and occlusion reasoning. In Proceedings of the IEEE International Conference on Computer Vision Workshops, pages 530-537, 2013. 3
[36] Bin Yang. Wenjie Luo, and Raquel Urtasun. Pixor: Real-time 3d object detection from point clouds. In Proceedings of the IEEE conference on Computer Vision and Pattern Recognition, pages 7652-7660, 2018. 1, 2, 5
[37] Tianwei Yin, Xingyi Zhou, and Philipp Krähenbühl. Center-based 3d object detection and tracking. arXiv: 2006.11275, 2020. 1, 2
[38] Edvin Listo Zec, Nasser Mohammadiha, and Alexander Schliep. Statistical sensor modelling for autonomous driving using autoregressive input-output hmms. In 2018 21st International Conference on Intelligent Transportation Systems (ITSC), pages 1331-1336. IEEE, 2018. 4

### Annexes

### A. Surrogate Network Architecture

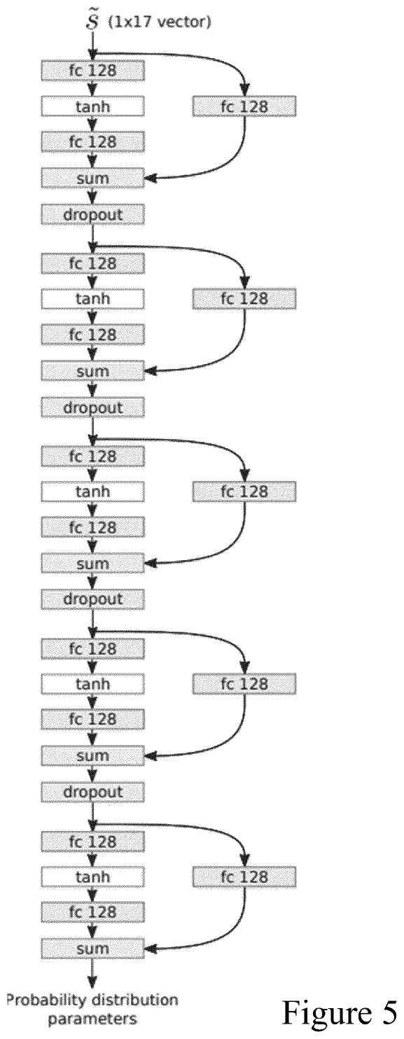

FIG. 5 schematically illustrates a network architecture for the surrogate, which is a multi-layered fully-connected network with skip connections, and dropout layers between ‘skip blocks’ (similar to a ResNet [13]), which is shown in the FIG. 5. The final layer of the network outputs the parameters of the underlying probability distributions.

### B. Experimental Hyperparameters

The hyperparameters used to train the surrogate models in the ACC experiment are shown in Table 6. Adam optimiser was used for all training. The hyperparameters were selected by manual tuning.

TABLE 6
Hyperparameters used to train the surrogate models in ACC experiment.

| | Neural | Logistic | Gaussian |
|---|---|---|---|
| | Surrogate | Regression | Fuzzer |
| Learning Rate | 1e−3 | 1e−2 | 1e−2 |
| Nᵢₜₑᵣₐₜᵢₒₙₛ | 20000 | 3000 | 3000 |
| Dropout Rate | 0.3 | N/A | N/A |
| Batch Size | 128 × 128 | 16 × 128 | 16 × 128 |

The hyperparameters used to train the neural network for the carla leaderboard evaluation are shown in Table 7.

TABLE 7
Hyperparameters used to train the surrogate
models in Carla leaderboard evaluation.

| | Neural Surrogate |
|---|---|
| Learning Rate | 1e−4 |
| Nᵢₜₑᵣₐₜᵢₒₙₛ | 50000 |
| Dropout Rate | 0.0 |
| Batch Size | 12000 |
| γ (Focal Loss) | 2.0 |
| α (Focal Loss) | 0.5 |

### C. Caria Simulator Configuration

The settings for the Carla lidar sensor are shown in Table 8.

### D. Planner Pseudo Code

A PID controller is used in combination with the planner in Listing 1 to control the vehicle throttle and brake.

TABLE 8
Lidar sensor configuration. The configuration is set to be
approximately equal to an Ouster lidar sensor [23].

| Property | Value |
|---|---|
| Sensor Position | x = 0.9, y = 0.0, z = 1.8 |
| Sensor Orientation | roll = 0.0, pitch = 0.0, yaw = 0.0 |
| Sensor Type | sensor.lidar.ray_cast |
| Rotation Frequency | 20 |
| Channels | 128 |
| Points per second | 2620000 |
| Upper Field of View | 11.25 |
| Lower Field of View | −11.25 |
| Range | 100 |
| Atmosphere attenuation rate | 0.004 |
| Noise stddev | 0.1 |
| Dropoff general rate | 0.45 |
| Dropoff intensity limit | 0.8 |
| Dropoff zero intensity | 0.9 |

Listing 1: Planner Pseudo Code

```
slow_threshold [symbol]  5
safe_stop_headway [symbol]  15
forward_horizon [symbol]  100
cruise_speed [symbol]  13.9
last_target_speed [symbol]  cruise_speed
lane_width [symbol]  4.5
time_threshold [symbol]  0.5
timestep [symbol]  0.05
in_lane [symbol]  filter(lambda x: abs(x.position.y) < land_width / 2, objects)
within_horizon [symbol]  filter(lambda x: x.position.x < forward_horizon,
in_lane)
slow [symbol]  list(filter(lambda x: x.speed < slow_threshold, within_horizon))
if len(slow) > 0:
  closest_agent [symbol]  sorted(slow, key [symbol] lambda x: x.position.x) [0]
  distance_to_closest [symbol]
  distance_to_closest_agent_vertex(closest_agent)
  distance_to_safe [symbol]  distance_to_closest [symbol]  safe_stop_headway
  if distance_to_safe < 0.1:
    target_speed [symbol]  0
  else:
    speed_of_closest [symbol]  closest_agent.speed
    if speed_of_closest < 0.5:
      speed_of_closest [symbol]  0
    accel [symbol]  (speed_of_closest [symbol]  2 [symbol]  last_target_speed [symbol]  2) / (2 [symbol]
    distance_to_safe)
    target_speed [symbol]  last_target_speed [symbol]  accel [symbol]  timestep
else:
  target_speed [symbol]  last_target_speed [symbol]  target_accel [symbol]  timestep [symbol]
indicates data missing or illegible when filed
```

E. Comparison with PKL Divergence

In this appendix we explain the relationship between the mean Euclidian norm metric, and the Planner KL divergence metric proposed by Philion et al. [25].

The KL divergence between the plan produced by an agent planning based on a detector and a surrogate model is given by:

$$P - KL = {E}_{p ( {s}^{1} \vert f ( x ) )} ( log \frac{{\prod }_{t = 1}^{t = T} p ( {z}_{l}^{1} \vert f ( x ) )}{{\prod }_{t = 1}^{t = T} \int p ( {z}_{l}^{1} \vert y ) p ( y \vert \tilde{s} ) dy} ) , \qquad ( 5 )$$

where zₜ^{l} is the position of ego at timestamp t, z¹={zₗ¹, . . . , z_{T}¹}, ƒ: x [symbol] y is the detector, p(zₗ¹|\tilde{s}) is the probabilistic planner, and p (y|\tilde{s}) is the probability distribution associated with the surrogate model for the detector, i.e. \tilde{ƒ}(y|\tilde{s})˜p(y|\tilde{ } s), which produces detections y∈γ from salient variables \tilde{s}.

The planner in our case is deterministic, so

$$p ( {z}_{l}^{1} \vert y ) = {1}_{\{ {z}_{l}^{1} \vert g ( y ) \}} \qquad ( 6 )$$

with the deterministic planning function g(y), which can be used to rewrite Equation 5 as

$${P - KL = - {\sum }_{t = 1}^{t = T} log ( \int p ( {z}_{l}^{1} \vert y ) p ( y \vert \tilde{s} ) dy ) \vert}_{{s}^{1} = g ( f ( x ) )} . \qquad ( 7 )$$

Approximating the integral ∫p(zₜ¹|y)p(y|\tilde{s})dy with a kernel density estimator with bandwidth h obtained by sampling n

1. A computer-implemented method of testing performance of a substitute upstream processing component, in order to determine whether the performance of the substitute upstream processing component is sufficient to support a downstream processing component, within an autonomous driving system, in place of an existing upstream processing component, the existing upstream processing component and the substitute upstream processing component mutually interchangeable in so far as they provide the same form of outputs interpretable by the downstream processing component, such that either upstream processing component may be used without modification to the downstream processing component, the method comprising:
applying the existing upstream processing component to a first set of upstream inputs, and thereby obtaining a first set of upstream outputs;
applying the downstream processing component to the first set of upstream outputs, thereby obtaining a first set of downstream outputs;
using the substitute upstream processing component to obtain a second set of upstream outputs for the first set of inputs;
applying the downstream processing component to the second set of upstream outputs, thereby obtaining a second set of downstream outputs; and
performing a metric-based comparison of the first and second sets of downstream outputs, thereby computing a numerical performance score for the substitute upstream processing component, the numerical performance score denoting an extent to which the second set of downstream outputs obtained using the substitute upstream processing component matches the first set of downstream outputs obtained using the existing upstream processing component.

2. A non-transitory computer readable medium embodying computer program instructions, the computer program instructions configured so as, when executed on one or more hardware processors, to implement operations for testing performance of a substitute upstream processing component, in order to determine whether the performance of the substitute upstream processing component is sufficient to support a downstream processing component, within an autonomous driving system, in place of an existing upstream processing component, the existing upstream processing component and the substitute upstream processing component mutually interchangeable in so far as they provide the same form of outputs interpretable by the downstream processing component, such that either upstream processing component may be used without modification to the downstream processing component, the operations comprising:
applying the existing upstream processing component to a first set of upstream inputs, and thereby obtaining a first set of upstream outputs;
applying the downstream processing component to the first set of upstream outputs, thereby obtaining a first set of downstream outputs;
using the substitute upstream processing component to obtain a second set of upstream outputs for the first set of inputs;
applying the downstream processing component to the second set of upstream outputs, thereby obtaining a second set of downstream outputs;
obtaining a ground truth set of outputs corresponding in form to the first and second sets of upstream outputs, the ground truth set of outputs and the first set of upstream inputs pertaining to a common driving scenario or scene;
applying the downstream processing component to the ground truth outputs directly, thereby obtaining a ground truth set of downstream outputs;
performing a first metric-based comparison of the first set of downstream outputs and the ground truth set of downstream outputs, thereby computing a first numerical performance score for the existing upstream processing component, the first numerical performance score denoting an extent to which the first set of downstream outputs obtained using the existing upstream processing component matches the ground truth set of downstream outputs; and
performing a second metric-based comparison of the second set of downstream outputs and the ground truth set of downstream outputs, thereby computing a second numerical performance score for the substitute upstream processing component, the second numerical performance score denoting an extent to which the second set of downstream outputs obtained using the substitute upstream processing component matches the ground truth set of downstream outputs.

3. The non-transitory computer readable medium of claim 2, wherein the ground truth outputs are obtained from real inputs via manual annotation, using offline processing, or using combination of manual annotation and offline processing.

4. The non-transitory computer readable medium of claim 2, wherein the ground truth outputs are simulated.

5. The non-transitory computer readable medium of claim 2, wherein an overall numerical performance score metric is derived from the first and second numerical performance scores, indicating an extent of difference between the first and second numerical performance scores.

6. The method of claim 1, comprising:
outputting the numerical performance score, the first numerical performance score, the second numerical performance and/or a overall numerical performance score at a graphical user interface, the overall numerical performance score being derived from the first and second numerical performance scores and indicating an extent of difference between the first and second numerical performance scores.

7. The method of claim 1, wherein the substitute upstream processing component is a surrogate model designed to approximate the existing upstream processing component, but constructed so as to operate on lower-fidelity inputs than the existing upstream processing component.

8. The method of claim 7, wherein the surrogate model is used to obtain the second set of upstream outputs for the first set of inputs by applying the surrogate model to a second set of upstream inputs of lower fidelity than the first set of upstream inputs, the first and second sets of upstream inputs pertaining to a common driving scenario or scene.

9. The method of claim 7, wherein the surrogate model is used to test the performance autonomous driving system based on low-fidelity simulation, in which the upstream processing component is replaced with the surrogate.

10. The method of claim 9, wherein a performance issue in the autonomous driving system is identified and mitigated via a modification to the autonomous driving system.

11. The method of claim 1, wherein the upstream processing component and the substitute upstream processing component operate on the same form of inputs.

12. The non-transitory computer readable medium of claim 2, wherein the downstream processing component is planning system and each set of downstream outputs is a sequence of spatial and motion states of a planned or realized trajectory, or a distribution over planned or realized trajectories.

13. The non-transitory computer readable medium of claim 12, wherein the existing upstream processing component comprises a perception component or a prediction component.

14. The method of claim 1, wherein the downstream processing component is a prediction system and each set of downstream outputs comprises a trajectory prediction.

15. The method of claim 14, wherein the existing upstream processing component comprises a perception component.

16. The method of claim 11, wherein the upstream processing component and the substitute upstream processing component are alternative perception components that both operate on sensor inputs.

17. A computer system for testing performance of a substitute upstream processing component, in order to determine whether the performance of the substitute upstream processing component is sufficient to support a downstream processing component, within an autonomous driving system, in place of an existing upstream processing component, the existing upstream processing component and the substitute upstream processing component mutually interchangeable in so far as they provide the same form of outputs interpretable by the downstream processing component, such that either upstream processing component may be used without modification to the downstream processing component, the computer system comprising:
at least one memory storing computer-readable instructions; and
at least one processor coupled to the at least one memory and configured to execute the computer-readable instructions, which upon execution cause the at least one processor to:
apply the existing upstream processing component to a first set of upstream inputs, and thereby obtaining a first set of upstream outputs;
apply the downstream processing component to the first set of upstream outputs, thereby obtaining a first set of downstream outputs;
use the substitute upstream processing component to obtain a second set of upstream outputs for the first set of inputs;
apply the downstream processing component to the second set of upstream outputs, thereby obtaining a second set of downstream outputs; and
perform a metric-based comparison of the first and second sets of downstream outputs, thereby computing a numerical performance score for the substitute upstream processing component, the numerical performance score denoting an extent to which the second set of downstream outputs obtained using the substitute upstream processing component matches the first set of downstream outputs obtained using the existing upstream processing component.

18. (canceled)

19. The non-transitory computer readable medium of claim 2, comprising: outputting the numerical performance score, the first numerical performance score, the second numerical performance and/or an overall numerical performance score at a graphical user interface, the overall numerical performance score being derived from the first and second numerical performance scores and indicating an extent of difference between the first and second numerical performance scores.

20. The non-transitory computer readable medium of claim 2, wherein the substitute upstream processing component is a surrogate model designed to approximate the existing upstream processing component, but constructed so as to operate on lower-fidelity inputs than the existing upstream processing component.

21. The non-transitory computer readable medium of claim 2, wherein the downstream processing component is a prediction system and each set of downstream outputs comprises a trajectory prediction.
